(19) United States
(12) Patent Application Publication
(10) Pub. No.: US 2026/0231699 A1
(43) Pub. Date: Aug. 6, 2026

(54) SEMICONDUCTOR STRUCTURE AND METHOD OF FORMING THEREOF

(71) Applicant: TAIWAN SEMICONDUCTOR MANUFACTURING COMPANY, LTD., Hsinchu (TW)

(72) Inventors: Yan-Ting LIN, Hsinchu County (TW); Chien-I KUO, Hsinchu County (TW); Ming-Hua YU, Hsinchu City (TW); Chii-Horng LI, Hsinchu County (TW)

(73) Assignee: TAIWAN SEMICONDUCTOR MANUFACTURING COMPANY, LTD., Hsinchu (TW)

(21) Appl. No.: 19/046,798

(22) Filed: Feb. 6, 2025

(51) Int. Cl. H01L 21/02; H10D 62/832; H10D 84/01; H10D 84/83

(52) U.S. Cl. CPC H10P 14/3466; H10D 84/013; H10D 84/8311; H10D 84/8312; H10D 84/832; H10D 62/832

(57) ABSTRACT

A method of forming a semiconductor structure includes a number of operations. A plurality of channel regions is formed over a substrate. First semiconductor material layers are formed on opposite sides of the channel regions, wherein growth rates of the first semiconductor material layers along a <110> direction and a <100> direction are controlled so that from a top view, an angle from a sidewall of one of the first semiconductor material layer to an interface of the one of the first semiconductor material layer and the corresponding channel region is in a range from about 54 degrees to about 90 degrees. Second semiconductor material layers are formed over the first semiconductor material layers, wherein the first and second semiconductor material layers form source/drain regions on the opposite sides of the channel regions. A gate structure is formed and wraps around the channel regions.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of gate-all-around field-effect transistors (GAA-FETs) in a three-dimensional view, in accordance with some embodiments.

FIGS. 2 through 5, 6A, 13A, 14A, 15A, 16A and 17A illustrate reference cross-section A-A′ illustrated in FIG. 1 that extends through a gate region along a longitudinal axis of the gate region.

FIGS. 6B, 7B, 8B, 9B, 10B, 11B, 12B, 13B, 14B, 15B, 16B, 17B and 18A illustrate cross-sectional views of reference cross-section B-B′ illustrated in FIG. 1 that extends through a fin along a longitudinal axis of the fin.

FIGS. 7A, 8A, 9A, 10A, 11A, 12A and 13C illustrate reference cross-section C-C′ illustrated in FIG. 1 that extends through source/drain regions along the longitudinal direction of the gate region.

FIGS. 12C and 12E illustrate schematic top views of the structure as illustrated in FIGS. 12A and 12B, in accordance with some embodiments.

FIG. 12D illustrates schematic cross-sectional views of source/drain regions of the structure as illustrated in FIGS. 12A and 12B, in accordance with some embodiments.

FIG. 18B illustrates schematic cross-sectional views of source/drain regions of the structure as illustrated in FIG. 18A, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The present disclosure is generally related to integrated circuit (IC) structures and methods of forming the same, and more particularly to fabricating gate-all-around (GAA) transistors, planar transistors, and/or fin field effect transistors (FinFET). It is also noted that the present disclosure presents embodiments in the form of multi-gate transistors. Multi-gate transistors include those transistors whose gate structures are formed on at least two-sides of a channel region. These multi-gate devices may include a p-type metal-oxide-semiconductor device or an n-type metal-oxide-semiconductor device. Specific examples may be presented and referred to herein as FinFET, on account of their fin-like structure. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), and/or other suitable channel configuration. Presented herein are embodiments of devices that may have one or more channel regions (e.g., nanosheets) associated with a single, contiguous gate structure. However, one of ordinary skill would recognize that the teaching can apply to a single channel (e.g., single nanosheet) or any number of channels. One of ordinary skill may recognize other examples of semiconductor devices that may benefit from aspects of the present disclosure.

Various embodiments relate to a semiconductor structure including transistors with channel regions in different dimensions. The dimension difference of the channel regions may cause source/drain regions formed on opposites of the channel regions to have different heights and different resistances. In one or more embodiments of the present disclosure, growth rates of the source/drain regions along different orientations are controlled, so that the height difference between the source/drain regions on the channel regions with different dimensions can be reduced. The contact uniformity of the transistors in the formed semiconductor structure can be improved.

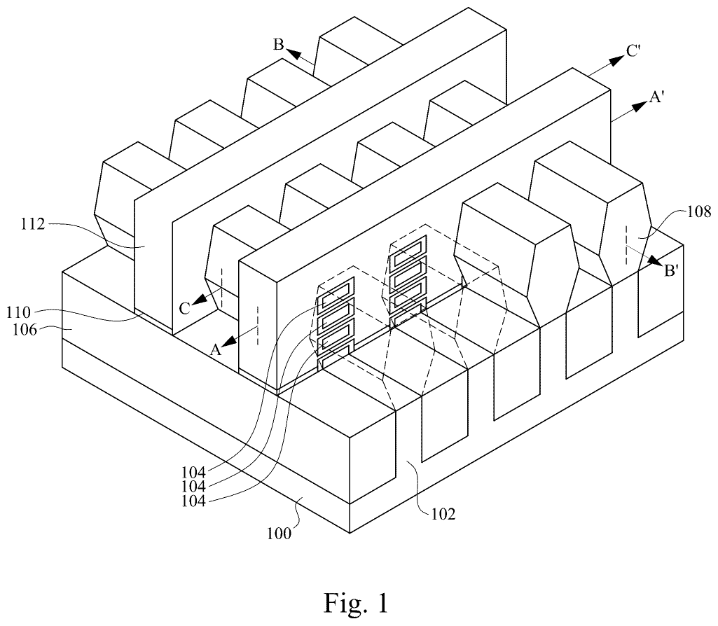

FIG. 1 illustrates an example of GAA-FETs (e.g., nanowire FETs, nanosheet FETs, or the like) in a three-dimensional view, in accordance with some embodiments. The GAA-FETs comprise nanostructures 104 (e.g., nanosheets, nanowires, nanorings, nanoslabs, or other structures having nano-scale size (e.g., a few nanometers)) over fins 102 on a substrate 100 (e.g., a semiconductor substrate), wherein the nanostructures 104 act as channel regions for the GAA-FETs. The nanostructure 104 may include p-type nanostructures, n-type nanostructures, or a combination thereof. Isolation regions 106 are disposed between adjacent fins 102, which may protrude above and from between neighboring isolation regions 106. Although the isolation regions 106 are described/illustrated as being separate from the substrate 100, as used herein, the term “substrate” may refer to the semiconductor substrate alone or a combination of the semiconductor substrate and the isolation regions. Additionally, although a bottom portion of the fins 102 are illustrated as being single, continuous materials with the substrate 100, the bottom portion of the fins 102 and/or the substrate 100 may comprise a single material or a plurality of materials. In this context, the fins 102 refer to the portion extending between the neighboring isolation regions 106.

Gate dielectrics 110 are over top surfaces of the fins 102 and along top surfaces, sidewalls, and bottom surfaces of the nanostructures 104. Gate electrodes 112 are over the gate dielectrics 110. Epitaxial source/drain regions 108 are disposed on the fins 102 on opposing sides of the gate dielectric layers 110 and the gate electrodes 112.

FIG. 1 further illustrates reference cross-sections that are used in later figures. Cross-section A-A′ is along a longitudinal axis of a gate electrode 112 and in a direction, for example, perpendicular to the direction of current flow between the epitaxial source/drain regions 108 of a GAA-FET. Cross-section B-B′ is perpendicular to cross-section A-A′ and is parallel to a longitudinal axis of a fin 102 of the GAA-FET and in a direction of, for example, a current flow between the epitaxial source/drain regions 108 of the GAA-FET. Cross-section C-C′ is parallel to cross-section A-A′ and extends through epitaxial source/drain regions of the GAA-FETs. Subsequent figures refer to these reference cross-sections for clarity.

Some embodiments discussed herein are discussed in the context of GAA-FETs formed using a gate-last process. In other embodiments, a gate-first process may be used. Also, some embodiments contemplate aspects used in planar devices, such as planar FETs or in fin field-effect transistors (FinFETs).

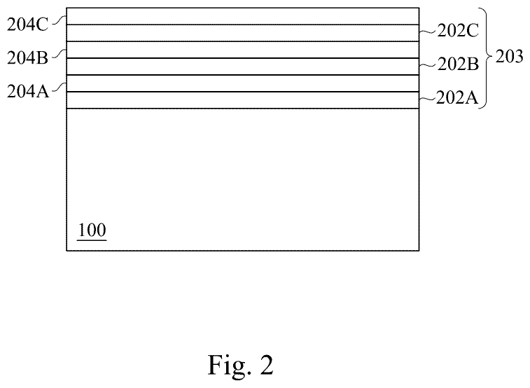

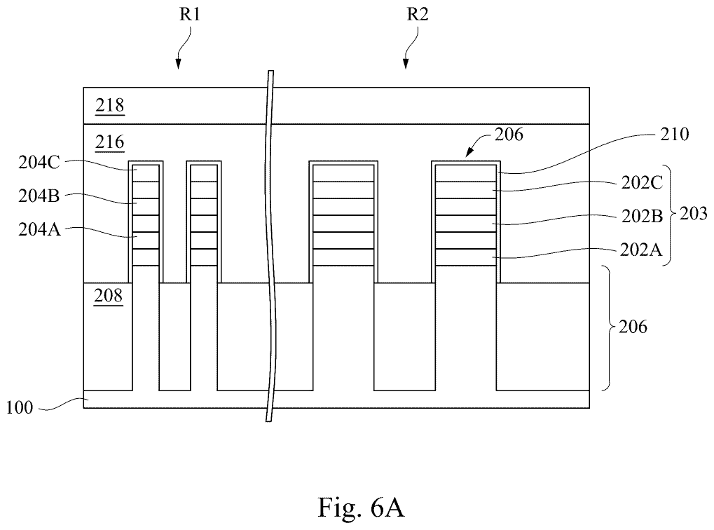

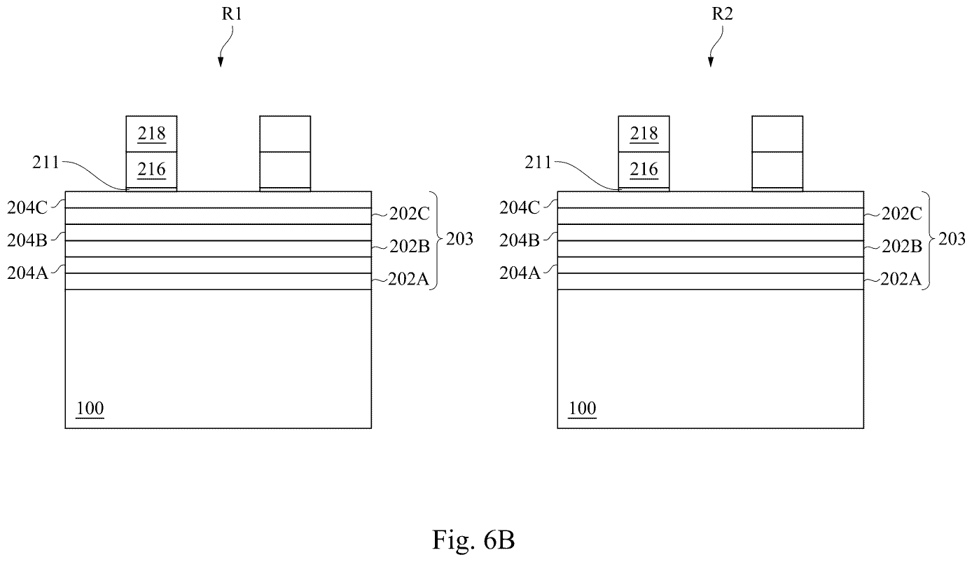

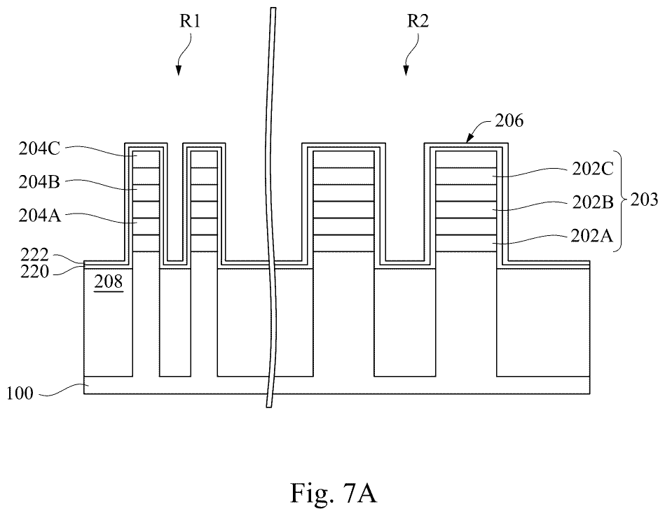

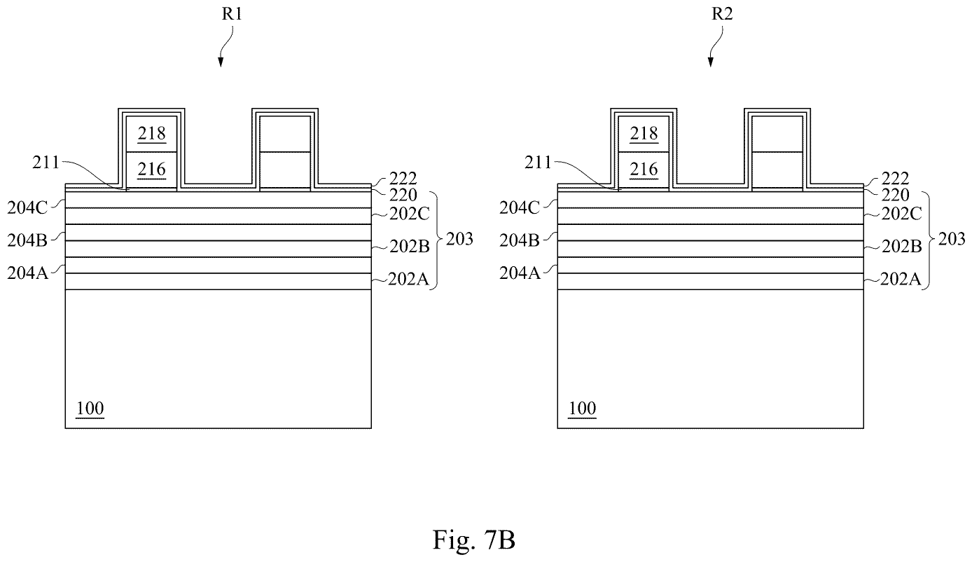

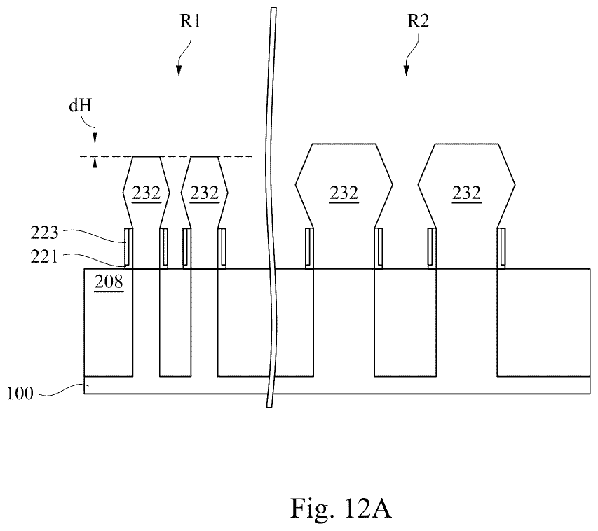

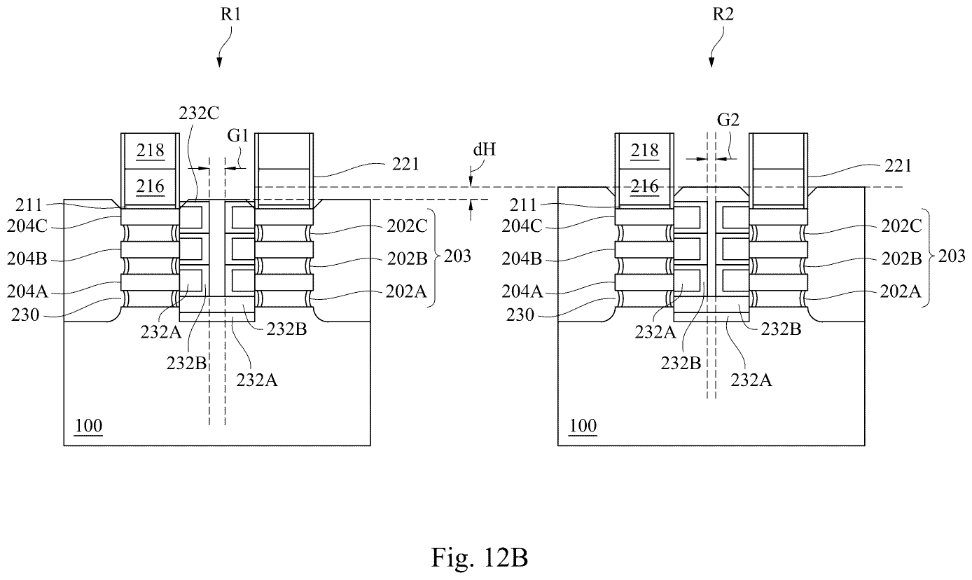

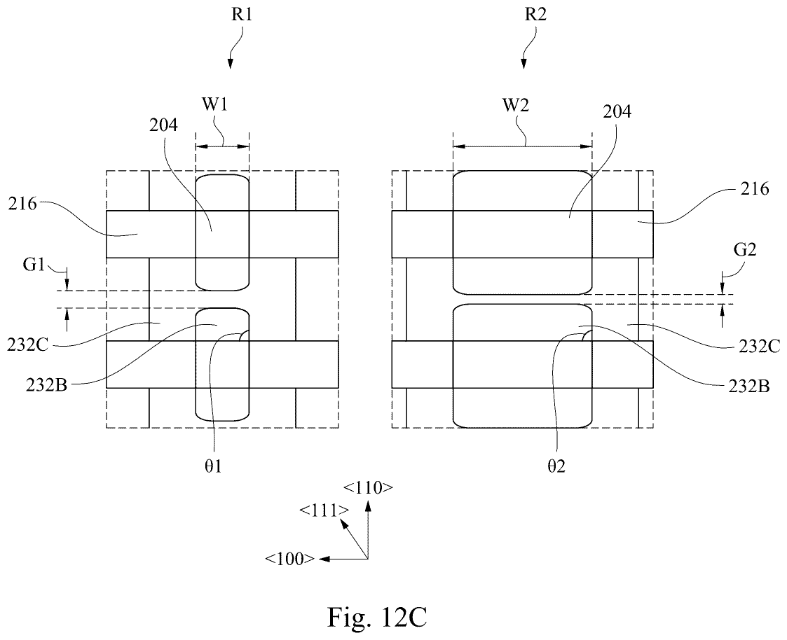

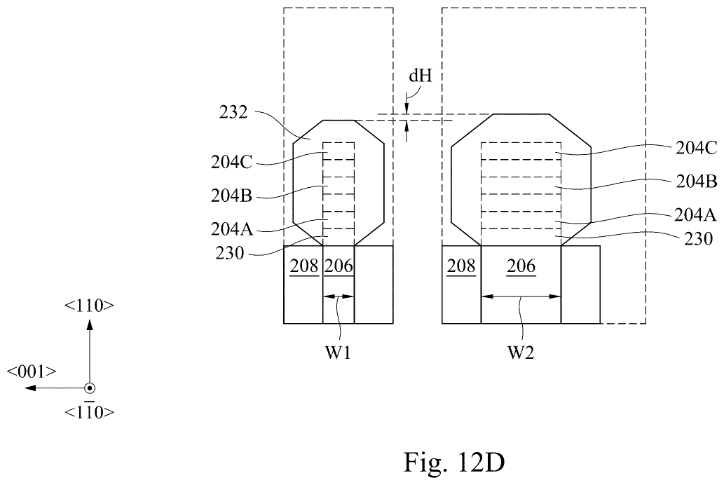

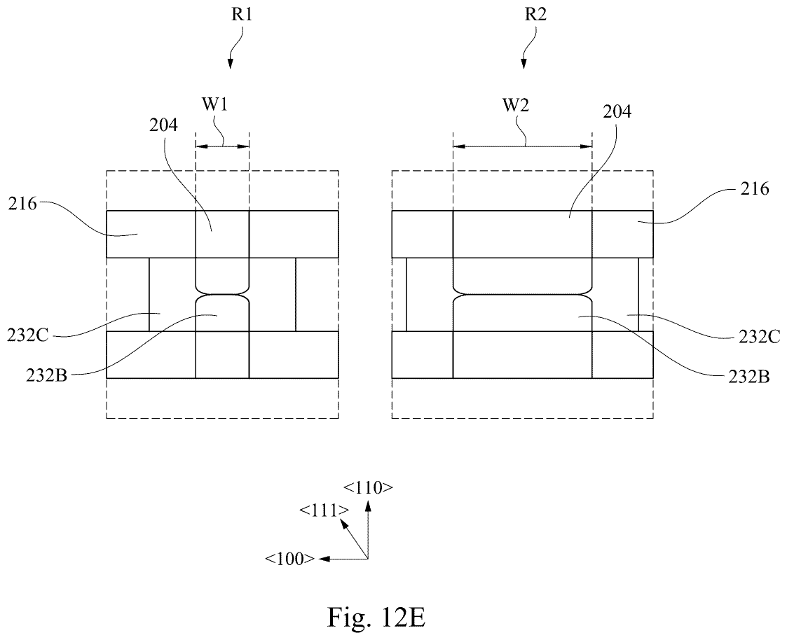

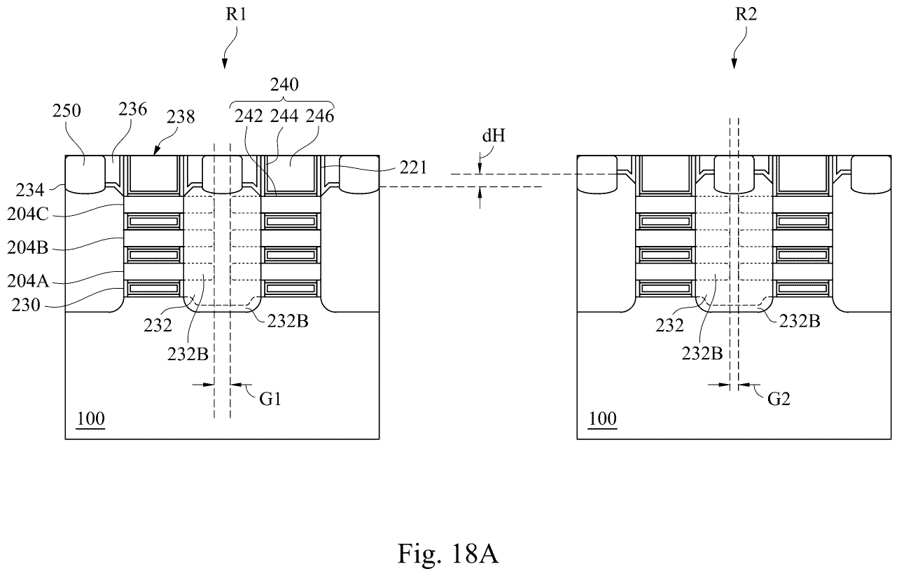

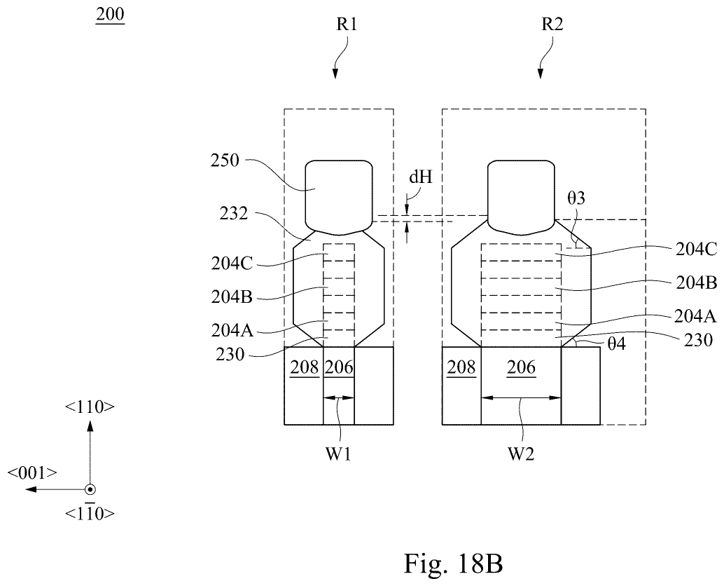

FIGS. 2 through 18B are cross-sectional views and top views of intermediate stages in the manufacturing of GAA-FETs, in accordance with some embodiments. FIGS. 2 through 5, 6A, 13A, 14A, 15A, 16A and 17A illustrate reference cross-section A-A′ illustrated in FIG. 1 that extends through a gate region along a longitudinal axis of the gate region. FIGS. 6B, 7B, 8B, 9B, 10B, 11B, 12B, 13B, 14B, 15B, 16B, 17B and 18A illustrate cross-sectional views of reference cross-section B-B′ illustrated in FIG. 1 that extends through a fin along a longitudinal axis of the fin. FIGS. 7A, 8A, 9A, 10A, 11A, 12A and 13C illustrate reference cross-section C-C′ illustrated in FIG. 1 that extends through source/drain regions along the longitudinal direction of the gate region. FIGS. 12C and 12E illustrate schematic top views of the structure as illustrated in FIGS. 12A and 12B, in accordance with some embodiments. FIG. 12E illustrates schematic cross-sectional views of source/drain regions of the structure as illustrated in FIGS. 12A and 12B, in accordance with some embodiments. FIG. 18B illustrates schematic cross-sectional views of source/drain regions of the structure as illustrated in FIG. 18A, in accordance with some embodiments.

Reference is made to FIG. 2. FIG. 2 illustrates forming a multi-layer stack 201 over a substrate 100, in accordance with some embodiments.

In FIG. 2, a substrate 100 is provided. The substrate 100 may be a semiconductor substrate, such as a bulk semiconductor, a semiconductor-on-insulator (SOI) substrate, or the like, which may be doped (e.g., with a p-type or an n-type dopant) or undoped. The substrate 100 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 100 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

Further in FIG. 2, a multi-layer stack 201 is formed over the substrate 100. The multi-layer stack 201 includes alternating layers of first semiconductor layers 202A-C (collectively referred to as first semiconductor layers 202) and second semiconductor layers 204A-C (collectively referred to as second semiconductor layers 204). For purposes of illustration and as discussed in greater detail below, the first semiconductor layers 202 will be removed and the second semiconductor layers 204 will be patterned to form channel regions of GAA-FETs.

The multi-layer stack 201 is illustrated as including three layers of each of the first semiconductor layers 202 and the second semiconductor layers 204 for illustrative purposes. In some embodiments, the multi-layer stack 201 may include any number of the first semiconductor layers 202 and the second semiconductor layers 204. Each of the layers of the multi-layer stack 201 may be epitaxially grown using a process such as chemical vapor deposition (CVD), atomic layer deposition (ALD), vapor phase epitaxy (VPE), molecular beam epitaxy (MBE), or the like. In various embodiments, the second semiconductor layers 204 may be formed of a semiconductor material suitable for serving as channel regions of GAA-FETs, such as silicon, silicon carbon, silicon germanium, or the like.

The first semiconductor materials and the second semiconductor materials may be materials having a high-etch selectivity to one another. As such, the first semiconductor layers 202 of the first semiconductor material may be removed without significantly removing the second semiconductor layers 204 of the second semiconductor material, thereby allowing the second semiconductor layers 204 to serve as channel regions of GAA-FETs.

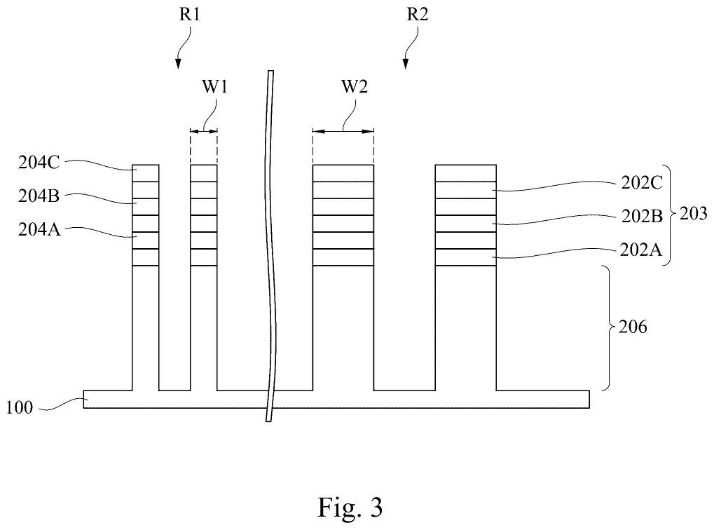

Reference is made to FIG. 3. FIG. 3 illustrates forming fin structures 206 and nanostructures 203, in accordance with some embodiments.

As illustrated in FIG. 3, fin structures 206 are formed in the substrate 100 and nanostructures 203 are formed in the multi-layer stack 201, in accordance with some embodiments. In some embodiments, the nanostructures 203 and the fin structures 206 may be formed in the multi-layer stack 201 and the substrate 100, respectively, by etching trenches in the multi-layer stack 201 and the substrate 100. Each fin structure 206 and overlying nanostructures 202A-202C and 204A-204C can be collectively referred to as a semiconductor fin extending from the substrate 100. The etching may be any acceptable etch process, such as a reactive ion etch (RIE), neutral beam etch (NBE), the like, or a combination thereof. The etching may be anisotropic. Forming the nanostructures 203 by etching the multi-layer stack 201 may further define first nanostructures 202A-C (collectively referred to as the first nanostructures 202) from the first semiconductor layers 202 and define second nanostructures 204A-C (collectively referred to as the second nanostructures 204) from the second semiconductor layers 204. The first nanostructures 202 and the second nanostructures 204 may further be collectively referred to as nanostructures 203.

The fin structures 206 and the nanostructures 203 may be patterned by any suitable method. For example, the fin structures 206 and the nanostructures 203 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures 206. While each of the fin structures 206 and the nanostructures 203 are illustrated as having a consistent width throughout, in other embodiments, the fin structures 206 and/or the nanostructures 203 may have tapered sidewalls such that a width of each of the fin structures 206 and/or the nanostructures 203 continuously increases in a direction towards the substrate 100. In such embodiments, each of the nanostructures 203 may have a different width and be trapezoidal in shape.

FIG. 3 illustrates the fin structures 206 and the nanostructures 203 in the different regions can have different dimensions.

FIG. 3 illustrates cross-sections across regions R1 and R2 on the substrate 100, in accordance with some embodiments. In the region R1, the fin structures 206 and the nanostructures 203 have a width W1. In the region R2, the fin structures 206 and the nanostructures 203 have a width W2. As illustrated in FIG. 3, the width W1 is less than W2. In some embodiments, the width W1 is in a range from about 5 nm to about 200 nm, the width W2 is in a range from about 5 nm to about 200 nm, and the width W1 is different from the width W2. For example, the width W1 or W2 can be less than about 5 nm, about 10 nm, about 20 nm, about 60 nm, about 100 nm, or about 200 nm.

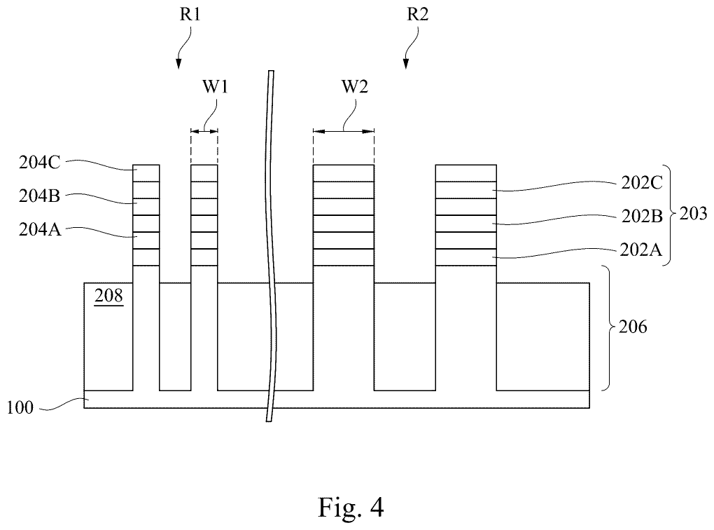

Reference is made to FIG. 4. FIG. 4 illustrates formation of shallow trench isolation (STI) regions 208 in the regions R1 and R2, in accordance with some embodiments.

In FIG. 4, shallow trench isolation (STI) regions 208 are formed adjacent the fin structures 206. The STI regions 208 may be formed by depositing an insulation material over the substrate 100, the fin structures 206, and nanostructures 203, and between adjacent fin structures 206. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 203. Although the insulation material is illustrated as a single layer, some embodiments may utilize multiple layers. For example, in some embodiments a liner (not separately illustrated) may first be formed along a surface of the substrate 100, the fin structures 206, and the nanostructures 203. Thereafter, a fill material, such as those discussed above may be formed over the liner.

A removal process is then applied to the insulation material to remove excess insulation material over the nanostructures 203. In some embodiments, a planarization process such as a chemical mechanical polish (CMP), an etch-back process, combinations thereof, or the like may be utilized. The planarization process exposes the nanostructures 203 such that top surfaces of the nanostructures 203 and the insulation material are level after the planarization process is complete.

The insulation material is then recessed to form the STI regions 208. The insulation material is recessed such that upper portions of fin structures 206 protrude from between neighboring STI regions 208. Further, the top surfaces of the STI regions 208 may have a flat surface as illustrated, a convex surface, a concave surface (such as dishing), or a combination thereof. The top surfaces of the STI regions 208 may be formed flat, convex, and/or concave by an appropriate etch. The STI regions 208 may be recessed using an acceptable etching process, such as one that is selective to the material of the insulation material (e.g., etches the material of the insulation material at a faster rate than the material of the fin structures 206 and the nanostructures 203). For example, an oxide removal using, for example, dilute hydrofluoric (dHF) acid may be used.

The process described above with respect to FIGS. 2 through 4 is just one example of how the fin structures 206 and the nanostructures 203 may be formed. In some embodiments, the fin structures 206 and/or the nanostructures 203 may be formed using a mask and an epitaxial growth process. For example, a dielectric layer can be formed over a top surface of the substrate 100, and trenches can be etched through the dielectric layer to expose the underlying substrate 100. Epitaxial structures can be epitaxially grown in the trenches, and the dielectric layer can be recessed such that the epitaxial structures protrude from the dielectric layer to form the fin structures 206 and/or the nanostructures 203. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Further in FIG. 4, appropriate wells (not separately illustrated) may be formed in the fin structures 206 and/or the nanostructures 203. In some embodiments, the appropriate wells are formed prior to formation of the nanostructures 203 and 204. In some embodiments with different well types in different device regions (e.g., NFET region and PFET region), different implant steps may be achieved using a photoresist or other masks (not separately illustrated). For example, a photoresist may be formed over the fin structures 206 and the STI regions 208 in the NFET region and the PFET region. The photoresist is patterned to expose the PFET region. The photoresist can be formed by using a spin-on technique and can be patterned using acceptable photolithography techniques. Once the photoresist is patterned, a first impurity (e.g., n-type impurity such as phosphorus, arsenic, antimony, or the like) implant is performed in the PFET region, and the photoresist may act as a mask to substantially prevent the first impurities from being implanted into the NFET region. After the implant, the photoresist is removed, such as by an acceptable ashing process.

Following or prior to the implanting of the PFET region, a photoresist or other masks (not separately illustrated) is formed over the fin structures 206, the nanostructures 203, and the STI regions 208 in the NFET region and the PFET region. The photoresist is then patterned to expose the NFET region. The photoresist can be formed by using a spin-on technique and can be patterned using acceptable photolithography techniques. Once the photoresist is patterned, a second impurity (e.g., p-type impurity such as boron, boron fluoride, indium, or the like) implant may be performed in the NFET region, and the photoresist may act as a mask to substantially prevent p-type impurities from being implanted into the PFET region. After the implant, the photoresist may be removed, such as by an acceptable ashing process.

After one or more well implants of the NFET region and PFET region, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

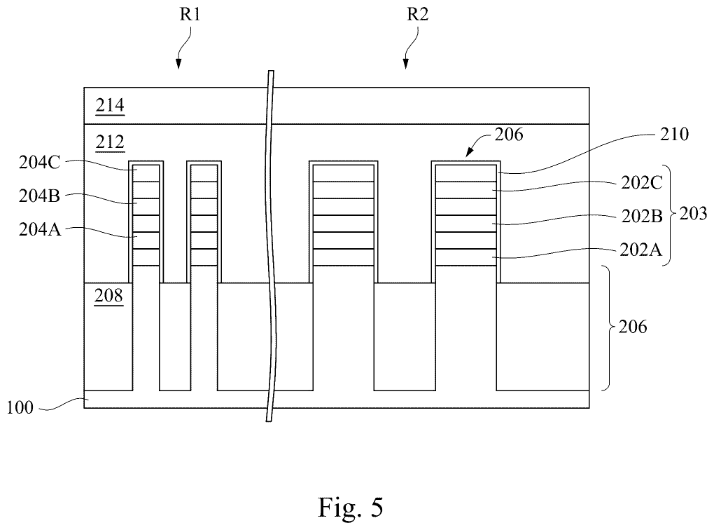

Reference is made to FIG. 5. FIG. 5 illustrates formation of a dummy gate structure, in accordance with some embodiments.

In FIG. 5, dummy dielectric layers 210 are formed on the fin structures 206 and/or the nanostructures 203 in the regions R1 and R2. The dummy dielectric layers 210 may be, for example, silicon oxide, silicon nitride, a combination thereof, or the like, and may be deposited or thermally grown according to acceptable techniques. A dummy gate layer 212 is formed over the dummy dielectric layers 210, and a mask layer 214 is formed over the dummy gate layer 212. The dummy gate layer 212 may be deposited over the dummy dielectric layers 210 and then planarized, such as by a CMP. The mask layer 214 may be deposited over the dummy gate layer 212. The dummy gate layer 212 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 212 may be deposited by physical vapor deposition (PVD), CVD, sputter deposition, or other techniques for depositing the selected material. The dummy gate layer 212 may be made of other materials that have a high etching selectivity from the etching of isolation regions. The mask layer 214 may include, for example, silicon nitride, silicon oxynitride, or the like. It is noted that the dummy dielectric layer 210 is shown covering only the fin structures 206 and the nanostructures 203 for illustrative purposes only. In some embodiments, the dummy dielectric layer 210 may be deposited such that the dummy dielectric layer 210 covers the STI regions 208, such that the dummy dielectric layer 210 extends between the dummy gate layer 212 and the STI regions 208.

Reference is made to FIGS. 6A and 6B. FIGS. 6A and 6B illustrate patterning the mask layer 214 and the dummy gate layer 212, in accordance with some embodiments.

In FIGS. 6A and 6B, the mask layer 214 (see FIG. 5) may be patterned using acceptable photolithography and etching techniques to form masks 218. The pattern of the masks 218 then may be transferred to the dummy gate layer 212 and to the dummy dielectric layer 210 to form dummy gates 216 and dummy gate dielectrics 211, respectively. The dummy gates 216 cover respective channel regions of the fin structures 206. The pattern of the masks 218 may be used to physically separate each of the dummy gates 216 from adjacent dummy gates 216. The dummy gates 216 may also have a lengthwise direction substantially perpendicular to the lengthwise direction of respective fin structures 206.

FIG. 6A illustrates reference cross-section A-A′ illustrated in FIG. 1 that extends through a gate region along a longitudinal axis of the gate region. In FIG. 6A, the dimension (e.g., the width W1) of the fin structures 206 and the nanostructures 203 in the region R1 is less than the dimension (e.g., the width W2) of the fin structures 206 and the nanostructures 203 in the region R2. FIG. 6B illustrates cross-sectional views of reference cross-section B-B′ illustrated in FIG. 1 that extends through a fin along a longitudinal axis of the fin, wherein FIG. 6B illustrates respective cross-sectional views of the fin structures 206 and the nanostructures 203 in the regions R1 and R2.

Reference is made to FIGS. 7A and 7B. FIGS. 7A and 7B illustrate forming spacer layers, in accordance with some embodiments.

In FIGS. 7A and 7B, a first spacer layer 220 and a second spacer layer 222 are formed over the structures illustrated in FIGS. 6A and 6B, respectively. The first spacer layer 220 and the second spacer layer 222 will be subsequently patterned to act as spacers for forming self-aligned source/drain regions. In FIGS. 7A and 7B, the first spacer layer 220 is formed on top surfaces of the STI regions 208; top surfaces and sidewalls of the fin structures 206, the nanostructures 203, and the masks 218; and sidewalls of the dummy gates 216 and the dummy gate dielectric 211. The second spacer layer 222 is deposited over the first spacer layer 220. The first spacer layer 220 may be formed of silicon oxide, silicon nitride, silicon oxynitride, or the like, using techniques such as thermal oxidation or deposited by CVD, ALD, or the like. The second spacer layer 222 may be formed of a material having a different etch rate than the material of the first spacer layer 220, such as silicon oxide, silicon nitride, silicon oxynitride, or the like, and may be deposited by CVD, ALD, or the like.

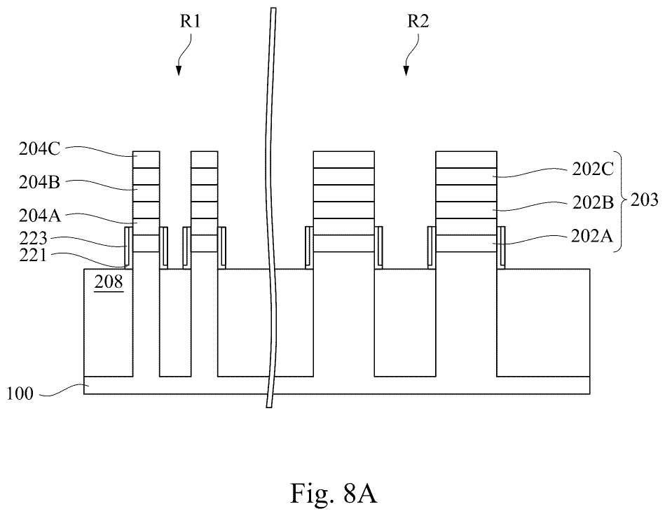

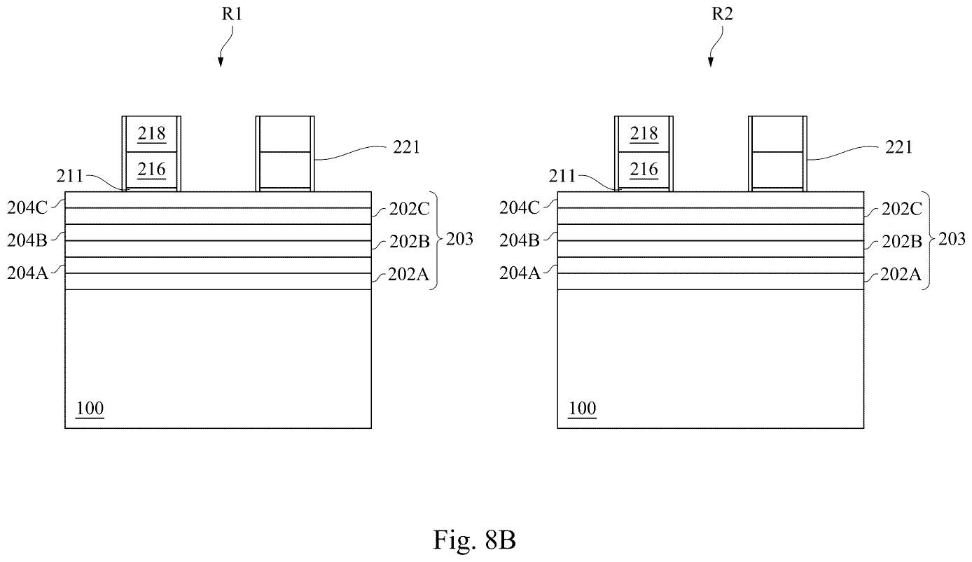

Reference is made to FIGS. 8A and 8B. FIGS. 8A and 8B illustrate formation gate spacers, in accordance with some embodiments.

In FIGS. 8A and 8B, the first spacer layer 220 and the second spacer layer 222 are etched to form first spacers 221 and second spacers 223. As will be discussed in greater detail below, the first spacers 221 and the second spacers 223 act to self-align subsequently formed source and drain regions (collectively referred to as source/drain regions), as well as to protect sidewalls of the fin structures 206 and/or nanostructures 203 during subsequent processing. The first spacer layer 220 and the second spacer layer 222 may be etched using a suitable etching process, such as an isotropic etching process (e.g., a wet etching process), an anisotropic etching process (e.g., a dry etching process), or the like. In some embodiments, the material of the second spacer layer 222 has a different etch rate than the material of the first spacer layer 220, such that the first spacer layer 220 may act as an etch stop layer when patterning the second spacer layer 222 and such that the second spacer layer 222 may act as a mask when patterning the first spacer layer 220. For example, the second spacer layer 222 may be etched using an anisotropic etch process wherein the first spacer layer 220 acts as an etch stop layer, wherein remaining portions of the second spacer layer 222 form second spacers 223 as illustrated in FIG. 8A. Thereafter, the second spacers 223 acts as a mask while etching exposed portions of the first spacer layer 220, thereby forming first spacers 221 as illustrated in FIG. 8A.

As illustrated in FIG. 8A, the first spacers 221 and the second spacers 223 are disposed on sidewalls of the fin structures 206 and/or nanostructures 203. In some embodiments, the spacers 221 and 223 only partially remain on sidewalls of the fin structures 206. In some embodiments, no spacer remains on sidewalls of the fin structures 206. As illustrated in FIG. 8B, in some embodiments, the second spacer layer 222 may be removed from over the first spacer layer 220 adjacent the masks 218, the dummy gates 216, and the dummy gate dielectrics 211, and the first spacers 221 are disposed on sidewalls of the masks 218, the dummy gates 216, and the dummy dielectric layers 211. In other embodiments, a portion of the second spacer layer 222 may remain over the first spacer layer 220 adjacent the masks 218, the dummy gates 216, and the dummy gate dielectrics 211.

In some embodiments, the first spacers 221 on gate sidewalls (also called gate spacers) have a small thickness (e.g., in a range from about 1 nm to about 10 nm) so as to reduce gate-to-gate pitch without significant reduction in source/drain region size. In some embodiments, the first spacers 221 on gate sidewalls is formed of as low-dielectric constant (low-k) materials (e.g., porous silicon oxide) having a k-value, for example, less than about 3.5. The low-k material can aid in reducing parasitic capacitance between, for example, the subsequently formed metal gates and source/drain contacts.

The above disclosure generally describes a process of forming spacers. Other processes and sequences may be used. For example, fewer or additional spacers may be utilized, different sequence of steps may be utilized (e.g., the first spacers 221 may be patterned prior to depositing the second spacer layer 222), additional spacers may be formed and removed, and/or the like.

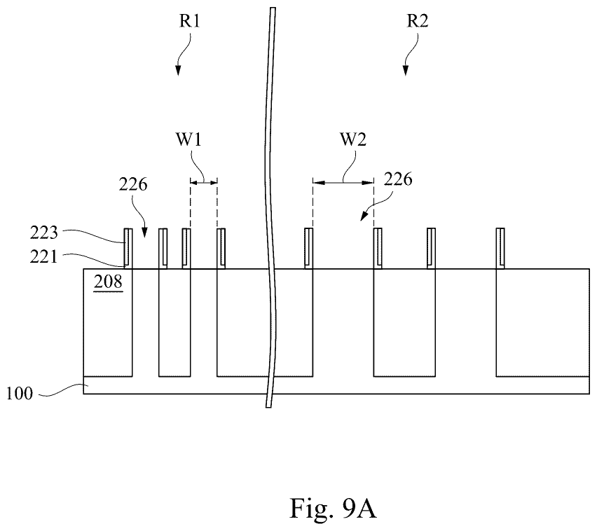

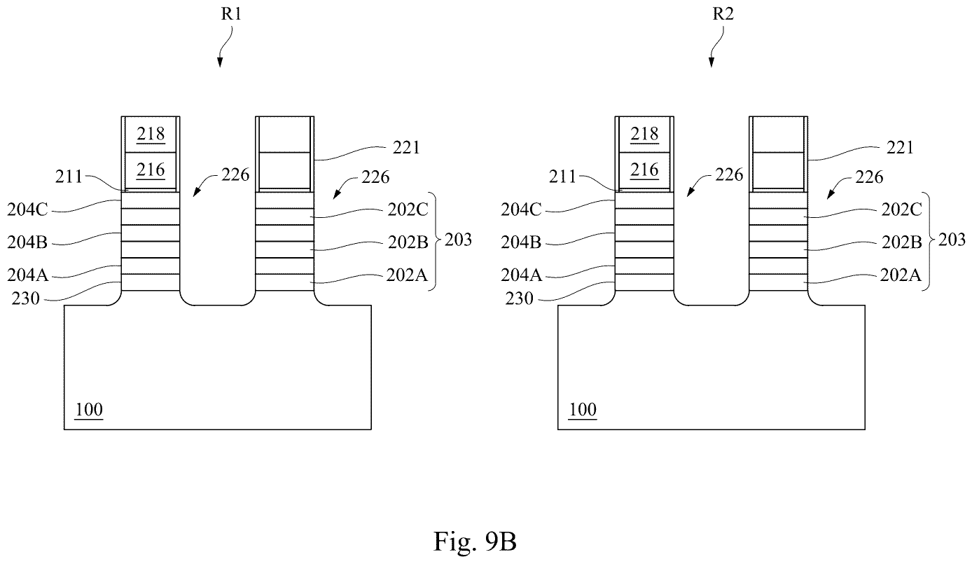

Reference is made to FIGS. 9A and 9B. FIGS. 9A and 9B illustrates forming source/drain recesses 226, in accordance with some embodiments.

In FIGS. 9A and 9B, source/drain recesses 226 are formed in the fin structures 206, the nanostructures 203, and the substrate 100, in accordance with some embodiments. Epitaxial source/drain regions will be subsequently formed in the source/drain recesses 226. The source/drain recesses 226 may extend through the first nanostructures 202 and the second nanostructures 204, and into the substrate 100. As illustrated in FIG. 9A, bottom surfaces of the source/drain recesses 226 may be level with top surfaces of the STI regions 208, as an example. In some other embodiments, the fin structures 206 may be etched such that bottom surfaces of the source/drain recesses 226 are disposed below the top surfaces of the STI regions 208, or above the top surfaces of the STI regions 208. The source/drain recesses 226 may be formed by etching the fin structures 206, the nanostructures 203, and the substrate 100 using anisotropic etching processes, such as RIE, NBE, or the like. The first spacers 221, the second spacers 223, and the masks 218 mask portions of the fin structures 206, the nanostructures 203, and the substrate 100 during the etching processes used to form the source/drain recesses 226. A single etch process or multiple etch processes may be used to etch each layer of the nanostructures 203 and/or the fin structures 206. Timed etch processes may be used to stop the etching of the source/drain recesses 226 after the source/drain recesses 226 reach a target depth.

FIG. 9A illustrate reference cross-section C-C′ illustrated in FIG. 1 that extends through source/drain regions along the longitudinal direction of the gate region. In FIG. 9A, the source/drain recesses 226 in the region R1 have a width W1, the source/drain recesses 226 in the region R2 have a width W2, and the width W1 is less than W2. FIG. 9B illustrates cross-sectional views of reference cross-section B-B′ illustrated in FIG. 1 that extends through a fin along a longitudinal axis of the fin, wherein FIG. 9B illustrates respective cross-section views of the regions R1 and R2. In the cross-section views as illustrated in FIG. 9B, the source/drain recesses 226 in the regions R1 and R2 have similar widths and similar depths.

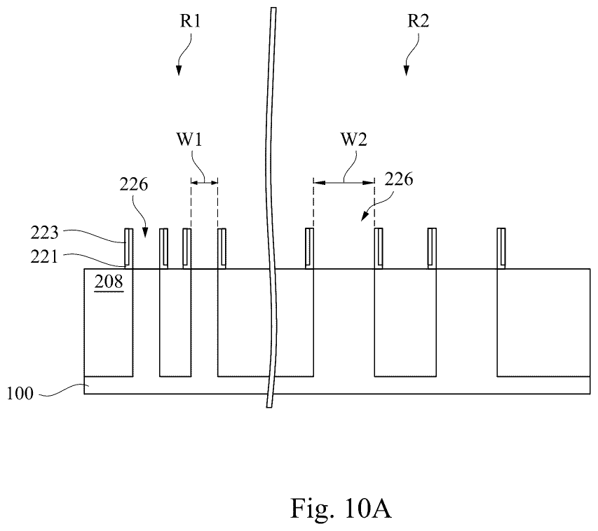

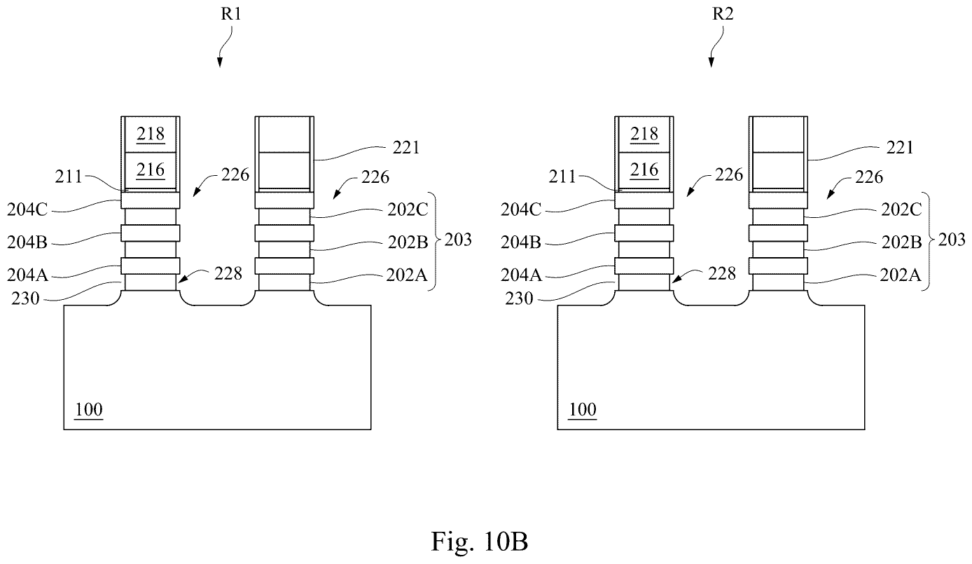

Reference is made to FIGS. 10A and 10B. FIGS. 10A and 10B illustrate laterally recessing the nanostructure of the nanostructures 204, in accordance with some embodiments.

In FIGS. 10A and 10B, portions of sidewalls of the layers of the multi-layer stack 203 formed of the first semiconductor materials (e.g., the first nanostructures 202) exposed by the source/drain recesses 226 are etched to form sidewall recesses 228 between corresponding second nanostructures 204. Although sidewalls of the first nanostructures 202 in recesses 228 are illustrated as being straight in FIG. 10B, the sidewalls may be concave or convex. The sidewalls may be etched using isotropic etching processes, such as wet etching or the like. In some embodiments in which the first nanostructures 202 include, e.g., SiGe, and the second nanostructures 204 include, e.g., Si or SiC, a dry etch process with tetramethylammonium hydroxide (TMAH), ammonium hydroxide (NH₄OH), or the like may be used to etch sidewalls of the first nanostructures 202.

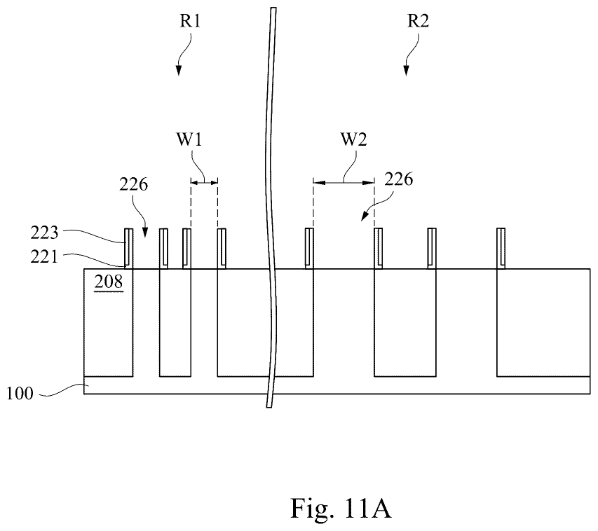

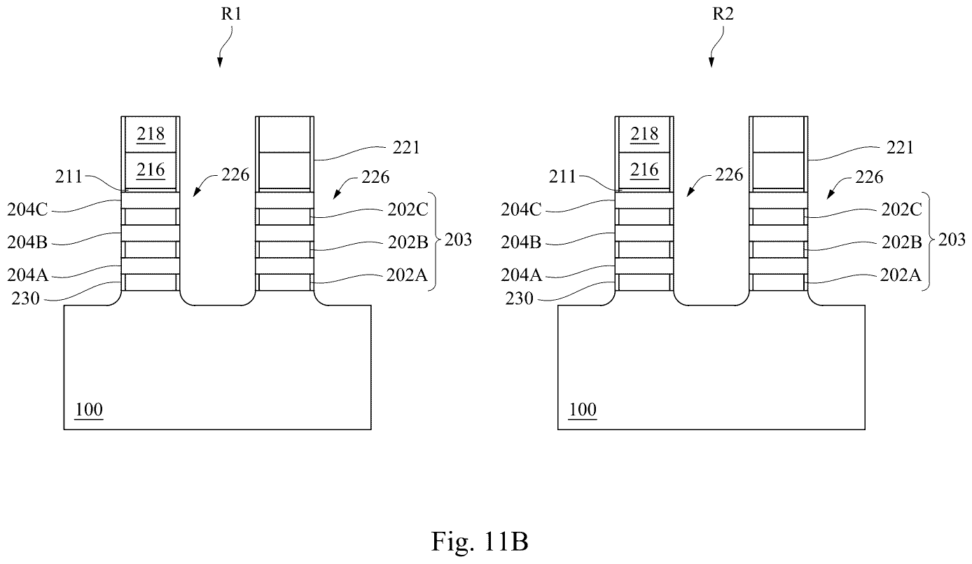

Reference is made to FIGS. 11A and 11B. FIGS. 11A and 11B illustrates forming inner spacers 230, in accordance with some embodiments.

In FIGS. 11A and 11B, inner spacers 230 are formed in the sidewall recess 228. The inner spacers 230 may be formed by depositing an inner spacer layer (not separately illustrated) over the structures illustrated in FIGS. 10A and 10B. The inner spacers 230 act as isolation features between subsequently formed source/drain regions and gate structure. As will be discussed in greater detail below, source/drain regions will be formed in the recesses 226, and the first nanostructures 202 will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 230. Although outer sidewalls of the inner spacers 230 are illustrated as being flush with sidewalls of the second nanostructures 204, the outer sidewalls of the inner spacers 230 may extend beyond or be recessed from sidewalls of the second nanostructures 204.

The outer sidewalls of the inner spacers 230 are illustrated as being straight in FIG. 11B. In some embodiments, the outer sidewalls of the inner spacers 230 may be concave or convex. The inner spacer layer may be etched by an anisotropic etching process, such as RIE, NBE, or the like. The inner spacers 230 may be used to prevent damage to subsequently formed source/drain regions (such as the epitaxial source/drain regions 232, discussed below with respect to FIGS. 12A through 12E) by subsequent etching processes, such as etching processes used to form gate structures.

Reference is made to FIGS. 12A through 12E. FIGS. 12A through 12E illustrate formation of source/drain epitaxial source/drain regions 232, in accordance with some embodiments.

FIG. 12A illustrate reference cross-section C-C′ illustrated in FIG. 1 that extends through source/drain regions along the longitudinal direction of the gate region. FIG. 12B illustrates cross-sectional views of reference cross-section B-B′ illustrated in FIG. 1 that extends through a fin along a longitudinal axis of the fin, wherein FIG. 12B illustrates respective cross-sectional views of the regions R1 and R2. In FIGS. 12A and 12B, epitaxial source/drain regions 232 are formed in the source/drain recesses 226.

In some embodiments, the source/drain regions 232 may exert stress on the second nanostructures 204, thereby improving device performance. As illustrated in FIG. 12B, the epitaxial source/drain regions 232 are formed in the source/drain recesses 226 such that each dummy gate 216 is disposed between respective neighboring pairs of the epitaxial source/drain regions 232. In some embodiments, the first spacers 221 are used to separate the epitaxial source/drain regions 232 from the dummy gates 212, and the inner spacers 230 are used to separate the epitaxial source/drain regions 232 from the first nanostructures 202 by an appropriate lateral distance so that the epitaxial source/drain regions 232 do not short out with subsequently formed gates of the resulting GAA-FETs.

In some embodiments, the epitaxial source/drain regions 232 may include any acceptable material appropriate for n-type GAA-FETs. For example, if the second nanostructures 204 are silicon, the epitaxial source/drain regions 232 may include materials exerting a tensile strain on the second nanostructures 204, such as silicon carbide, phosphorous doped silicon carbide, silicon phosphide, or the like. In some embodiments, the epitaxial source/drain regions 232 may include any acceptable material appropriate for p-type GAA-FETs. For example, if the second nanostructures 204 are silicon, the epitaxial source/drain regions 232 may comprise materials exerting a compressive strain on the second nanostructures 204, such as silicon germanium, boron doped silicon germanium, germanium, germanium tin, or the like. The epitaxial source/drain regions 232 may have surfaces raised from respective upper surfaces of the nanostructures 203 and may have facets.

The epitaxial source/drain regions 232 may be implanted with dopants to form source/drain regions, followed by an anneal. The source/drain regions may have an impurity concentration of between about 1×10¹⁷ atoms/cm³ and about 1×10²² atoms/cm³. The n-type and/or p-type impurities for source/drain regions may be any of the impurities previously discussed. In some embodiments, the epitaxial source/drain regions 232 may be in situ doped during growth.

As a result of the epitaxy processes used to form the epitaxial source/drain regions 232, upper surfaces of the epitaxial source/drain regions 232 have facets which expand laterally outward beyond sidewalls of the nanostructures 203. As illustrated in FIG. 12A, adjacent epitaxial source/drain regions 232 remain separated after the epitaxy process is completed. In some embodiments, facets of the upper surfaces of the epitaxial source/drain regions 232 cause adjacent epitaxial source/drain regions 232 to merge. In FIG. 12A, the first spacers 221, 223 may be formed to a top surface of the STI regions 208 thereby blocking the lateral epitaxial growth. In some embodiments, the spacer etch used to form the first spacers 221, 223 may be adjusted to remove the spacer material to allow the epitaxially grown region to extend to the surface of the STI region 208.

In one or more embodiments of the present disclosure, the epitaxial source/drain regions 232 may include one or more semiconductor material layers. For example, the epitaxial source/drain regions 232 may include a first semiconductor material layer 232A, a second semiconductor material layer 232B, and a third semiconductor material layer 232C, which are distinguished in FIG. 12B by using dash lines. Any number of semiconductor material layers may be used for the epitaxial source/drain regions 232. Each of the first semiconductor material layer 232A, the second semiconductor material layer 232B, and the third semiconductor material layer 232C may be formed of different semiconductor materials and may be doped to different dopant concentrations. In embodiments in which the epitaxial source/drain regions 232 include three semiconductor material layers, the first semiconductor material layer 232A may be deposited over surfaces of the nanostructures 204 and the substrate 100 exposed from the source/drain recesses 226, the second semiconductor material layer 232B may be deposited over the first semiconductor material layer 232A, and the third semiconductor material layer 232C may be deposited over the second semiconductor material layer 232B.

In some embodiments, the epitaxial source/drain regions 232 may be formed by an epitaxy or epitaxial (epi) process. The epi process may include a selective epitaxial growth (SEG) process, CVD deposition techniques (e.g., vapor-phase epitaxy (VPE) and/or ultra-high vacuum CVD (UHV-CVD)), molecular beam epitaxy, or other suitable epi processes. The epitaxial source/drain regions 232, the nanostructures 202, 204, and/or the fin structure 206 may be implanted with impurities, similar to the process previously described for forming LDD regions, followed by an anneal. In some embodiments, the epitaxial source/drain regions 232 are in-situ doped or undoped during the epi process. When the epitaxial source/drain regions 232 are undoped, they may be doped in a subsequent process. The doping may be achieved by an ion implantation process, plasma immersion ion implantation (PIII) process, gas and/or solid source diffusion process, or other suitable process. Afterwards, the epitaxial source/drain regions 232 may be exposed further to annealing processes, such as a rapid thermal annealing process.

FIGS. 12A and 12B illustrate cross-sectional views of the regions R1 and R2, in accordance with some embodiments. In one or more embodiments of the present disclosure, the regions R1 and R2 are p-type regions, which can be for forming p-type devices, such as PMOS transistors, e.g., p-type nano-FETs. The substrate 100 may be lightly doped with n-type impurity. An anti-punch-through (APT) implantation may be performed on an upper portion of the substrate 100 to form an APT region. During the APT implantation, impurities may be implanted in the substrate 100. The impurities may have a conductivity type opposite from a conductivity type of source/drain regions that will be subsequently formed in each of the p-type regions R1 and R2. The APT region may extend under the source/drain regions in the nano-FETs. The APT region may be used to reduce the leakage from the source/drain regions to the substrate 100. In some embodiments, the doping concentration in the APT region may be in the range of about 10¹⁸ cm⁻³ to about 10¹⁹ cm⁻³.

In some embodiments, the substrate 100 has (110) surface orientation. This surface orientation can be used to control the orientation of the layers (e.g., a multi-layer stack 52) which are formed above the substrate 100. For example, the first nanostructures 202 and the second nanostructures 204 of the nanostructures 203 formed on the (110) surface orientation substrate 100 also can have (110) surface orientation. The (110) surface orientation nanostructures 204 can act as channel layers and improves device performance (I_{deff}) due to a higher hole mobility on <110>/(110) than <110>/(001). Furthermore, the arrangement of some layers which are above the substrate 100 may be influenced by the surface orientations of the substrate 100.

The (110) surface orientation of the substrate 100 can be used to assist in formation of the source/drain regions 232. For example, the orientation of the first semiconductor material layer 232A is dependent on the orientation of the second nanostructure 204. The orientation of the first and second nanostructures 202 and 204 are dependent on the orientation of the substrate 100. Therefore, a rectangular cross-sectional profile of the first semiconductor material layer 232A is formed due to the surface orientations of the substrate 100. As mentioned above, the substrate 100 is designed to have the (110) surface orientation. The second nanostructures 204 formed on the (110) surface orientation substrate 100 also can have (110) surface orientation due to the epitaxial growth behavior. The first semiconductor material layer 232A formed on the (110) surface orientation nanostructure 204 can grow along a vertical direction and a horizontal direction resulting in the rectangular-like cross-sectional profile due to the epitaxial growth behavior.

FIG. 12C illustrates a schematic top view of the structure as illustrated in FIGS. 12A and 12B, in accordance with some embodiments. FIG. 12D illustrates schematic cross-sectional views of source/drain regions of the structure as illustrated in FIGS. 12A and 12B, in accordance with some embodiments. FIGS. 12C and 12D illustrate one or more of the source/drain regions 232, the nanostructures 204, the inner spacers 230, the STI regions 208 and the fin structures 206, and other elements are not illustrated in FIGS. 12C and 12D for the purpose of simplicity and clarity.

FIG. 12C illustrates formation the second semiconductor material layer 232B from a schematic top view. In one or more embodiments of the present disclosure, a growth rate of the second semiconductor material layer 232B along the <100> direction can be similar to or the same as a growth rate of the second semiconductor material layer 232B along the <110> direction. The second semiconductor material layers 232B may have a rectangular-like profiles in the regions R1 and R2 from the schematic top view as shown in FIG. 12C, wherein the dimensions of the nanostructures 204 in the regions R1 and R2 are different. The nanostructures 204 in the region R1 have the width W1. The nanostructures 204 in the region R2 have the width W2. In FIG. 12C, the second semiconductor material layer 232B in the region R1 has an angle θ1 from a sidewall of the second semiconductor material layer 232B to an interface of the second semiconductor material layer 232B and the nanostructures 204, and the second semiconductor material layer 232B in the region R2 has an angle θ2 from a sidewall of the second semiconductor material layer 232B to an interface of the second semiconductor material layer 232B and the nanostructures 204. The angle θ1 of the second semiconductor material layer 232B in the region R1 may be similar to the angle θ2 of the second semiconductor material layer 232B in the region R2 since the ratio of the growth rates of second semiconductor material layer 232B along the <110> direction and the <100> direction are controlled to be similar or the same. In some embodiments, each of the angles θ1 and θ2 is in a range from about 54 degrees to about 90 degrees.

As illustrated in FIGS. 12B and 12C, a gap G1 is between the adjacent second semiconductor material layers 232B in the region R1 and a gap G2 is between the adjacent second semiconductor material layers 232B in the region R2. In some embodiments, the gap G1 is less than or equal to the gap G2. In some embodiments, a difference between the gaps G1 and G2 is in a range from about numbers of angstroms to about 5 nm.

After the second semiconductor material layers 232B are formed, the third semiconductor material layers 232C are formed over the second semiconductor material layers 232B to fill with the gap G1 in the region R1 and fill with the gap G2 in the region R2. As illustrated in FIGS. 12A through 12D, a top surface of the source/drain regions 232 in the region R1 is lower than a top surface of the source/drain regions 232 in the region R2. Since the second semiconductor material layers 232B in the regions R1 and R2 are uniformly formed, the source/drain regions 232 on the nanostructures 204 with the width W1 in the region R1 may have a height close to a height of the source/drain regions 232 on the nanostructures 204 with the width W2 in the region R2. In some embodiments, a height different dH between the source/drain regions 232 in the regions R1 and R2 is in a range from 0 nm to about 50 nm.

In one or more embodiments of the present disclosure, the semiconductor material layers 232A, 232B and 232C in the p-type regions R1 and R2 may be epitaxially grown silicon germanium (SiGe). The semiconductor material layers 232A, 232B and 232C may be suitably doped with a p-type dopant such as boron. For example, the first semiconductor material layer 232A may be referred to as Si_{1-x_L0}Ge_{x_L0}, the second semiconductor material layer 232B may be referred to as Si_{1-x_L1}Ge_{x_L1}: B, and the third semiconductor material layer 232C may be referred to as Si_{1-x_L2}Ge_{x_L2}: B, wherein the labels L0, L1 and L2 present germanium atomic concentrations in the semiconductor material layers 232A, 232B and 232C.

In some embodiments, the formation of the first semiconductor material layer 232A is performed at a process temperature in a range from about 500° C. to about 650° C. In some embodiments, the first semiconductor material layer 232A may have a boron concentration less than or equal to about 1×10²¹ cm⁻³. In some embodiments, the first semiconductor material layer 232A having a germanium atomic concentration less than about 10 at. %. In some embodiments, the first semiconductor material layer 232A having a germanium atomic concentration in a range from about 0 at. % to about 10 at. %. In some embodiments, the first semiconductor material layer 232A is free from germanium.

In some embodiments, the formation of the second semiconductor material layer 232B is performed at a process temperature in a range from about 400° C. to about 500° C. The process temperature of forming the second semiconductor material layer 232B may be less than the process temperature of forming the first semiconductor material layer 232A to have uniform growth rates along the <110> direction and the <100> direction. In some embodiments, the second semiconductor material layer 232B may have a boron concentration less than or equal to about 7×10²⁰ cm⁻³. In some embodiments, the second semiconductor material layer 232B having a germanium atomic concentration equal to about 40 at. %. In some embodiments, the second semiconductor material layer 232B having a germanium atomic concentration in a range from about 10 at. % to about 40 at. %. In some embodiments, the second semiconductor material layer 232B having a germanium atomic concentration equal to about 40 at. %. In some embodiments, the germanium atomic concentration of the second semiconductor material layer 232B is greater than the germanium atomic concentration of the first semiconductor material layer 232A.

In some embodiments, in the regions R1 and R2, the formation of the first semiconductor material layer 232A and the second semiconductor material layer 232B are controlled to have uniform growth rates in the <110> direction and the <100> direction. In other words, FIG. 12C illustrates that the second semiconductor material layer 232B are formed and extend in the <111> direction, which is at a plane of the <110> direction and the <100> direction. The angles θ1 and θ2 are controlled to be similar or the same. In some embodiments, as illustrated in FIG. 12C, when the angles θ1 and θ2 are close to 90 degrees, the adjacent second semiconductor material layer 232B in the region R1 have adjacent near-flat surfaces spaced apart from each other by the gap G1, and the second semiconductor material layer 232B in the region R2 have adjacent near-flat surfaces spaced apart from each other by the gap G2. In some embodiments, as illustrated in 12C, the second semiconductor material layers 232B have rectangular profiles in the regions R1 and R2 from the top view as illustrated in FIG. 12C.

In some embodiments, the formation of the third semiconductor material layer 232C is performed at a process temperature in a range from about 400° C. to about 450° C. In some embodiments, the third semiconductor material layer 232C may have a boron concentration greater than about 7×10²⁰ cm⁻³. In some embodiments, the boron concentration of the third semiconductor material layer 232C is greater than the boron concentration of second semiconductor material layer 232B.

In some embodiments, the third semiconductor material layer 232C having a germanium atomic concentration equal to about 40 at. %. In some embodiments, the third semiconductor material layer 232C having a germanium atomic concentration in a range from about 40 at. % to about 90 at. %. In some embodiments, the third semiconductor material layer 232C having a germanium atomic concentration equal to about 90 at. %. In some embodiments, the germanium atomic concentration of the third semiconductor material layer 232C is greater than the germanium atomic concentration of the second semiconductor material layer 232B.

FIG. 12E illustrates a schematic top view of the structure as illustrated in FIGS. 12A and 12B, in accordance with some embodiments. In FIG. 12E, the adjacent second semiconductor material layers 232B in both of the regions R1 and R2 are formed to merge, and the gaps G1 and G2 are reduced to be zero.

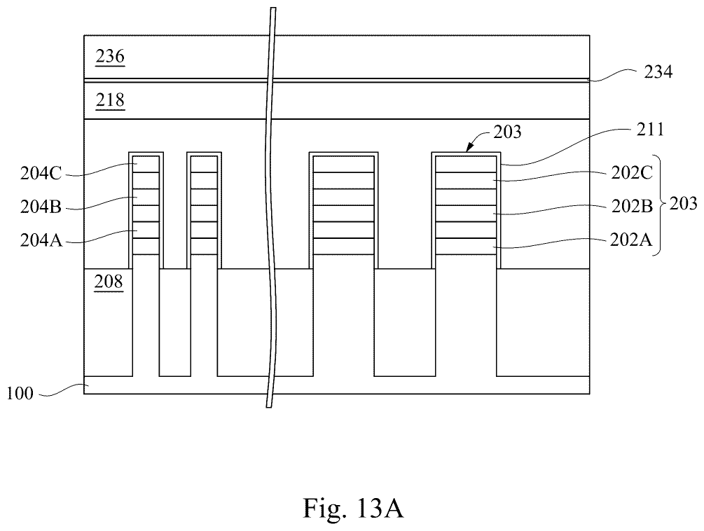

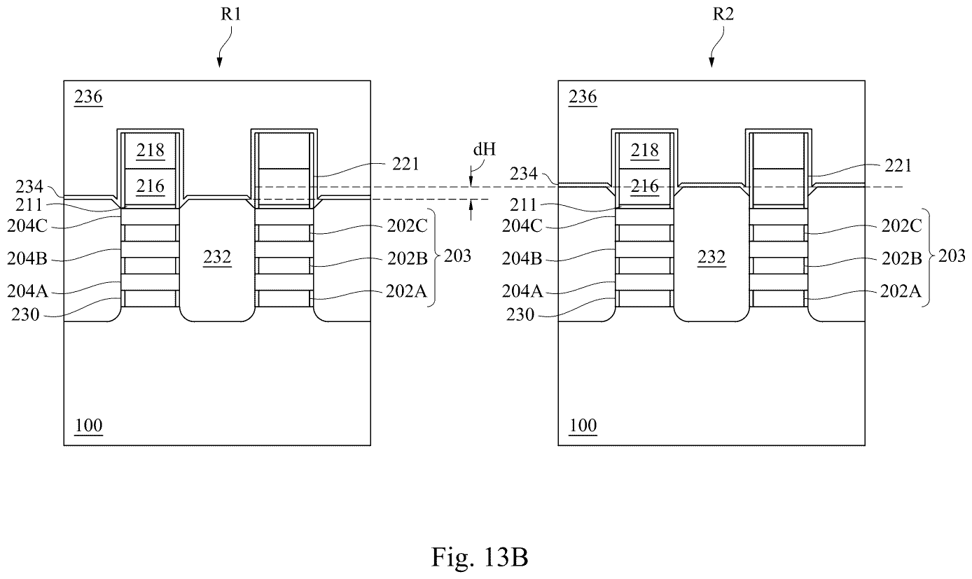

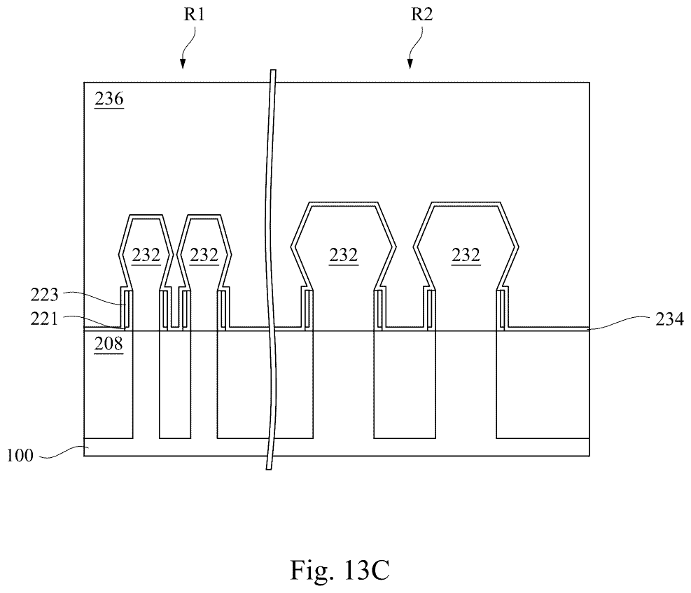

Reference is made to FIGS. 13A through 13C. FIGS. 13A through 13C illustrate forming an interlayer dielectric (ILD) layer 236 and a contact etch stop layer (CESL) 234, in accordance with some embodiments.

In FIGS. 13A-13C, an interlayer dielectric (ILD) layer 236 is deposited over the structure illustrated in FIGS. 12A-12D. The ILD layer 236 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 234 is disposed between the ILD layer 236 and the epitaxial source/drain regions 232, the masks 214, and the first spacers 221. The CESL 234 may comprise a dielectric material, such as, SiN, SiOₓ, SiCN, SiON, SiOCN, Al₂O₃, HfO₂, ZrO₂, HfAlOₓ, and HfSiOₓ, or the like, having a different etch rate than the material of the overlying ILD layer 236.

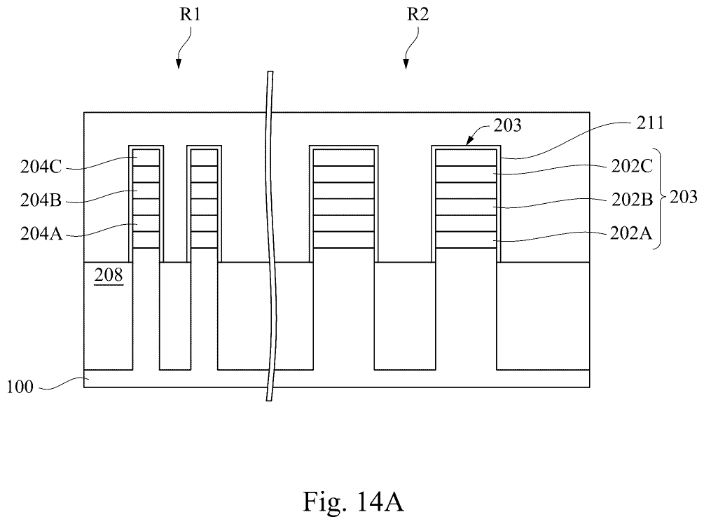

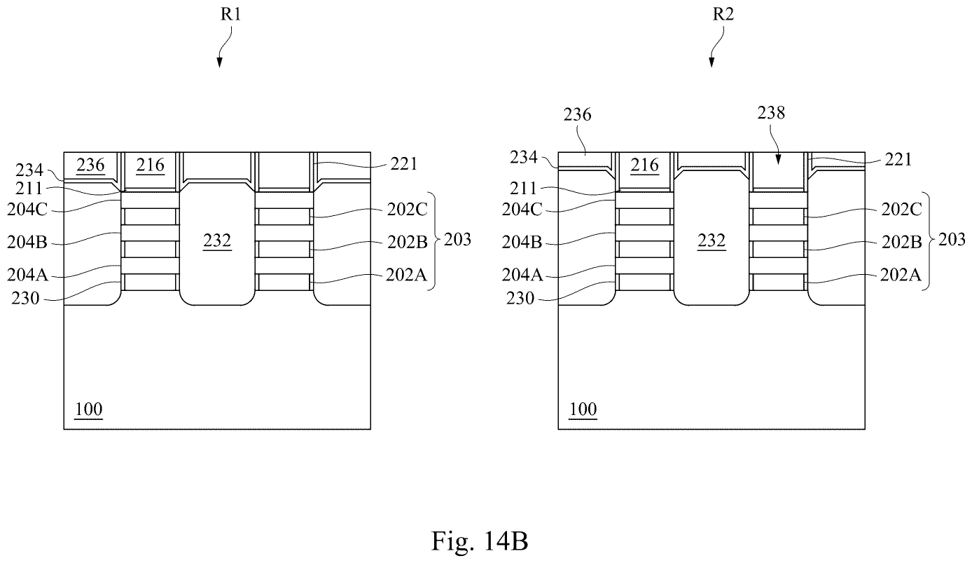

Reference is made to FIGS. 14A and 14B. FIGS. 14A and 14B illustrate performing a planarization process on the structure as illustrated in FIGS. 13A through 13C, in accordance with some embodiments.

In FIGS. 14A-14B, a planarization process, such as a CMP, may be performed to level the top surface of the ILD layer 236 with the top surfaces of the dummy gates 216 or the masks 218. The planarization process may also remove the masks 218 on the dummy gates 216, and portions of the first spacers 221 along sidewalls of the masks 218. After the planarization process, top surfaces of the dummy gates 216, the first spacers 221, and the ILD layer 236 are level within process variations. Accordingly, the top surfaces of the dummy gates 212 are exposed through the ILD layer 236. In some embodiments, the masks 218 may remain, in which case the planarization process levels the top surface of the ILD layer 236 with top surface of the masks 218 and the first spacers 221.

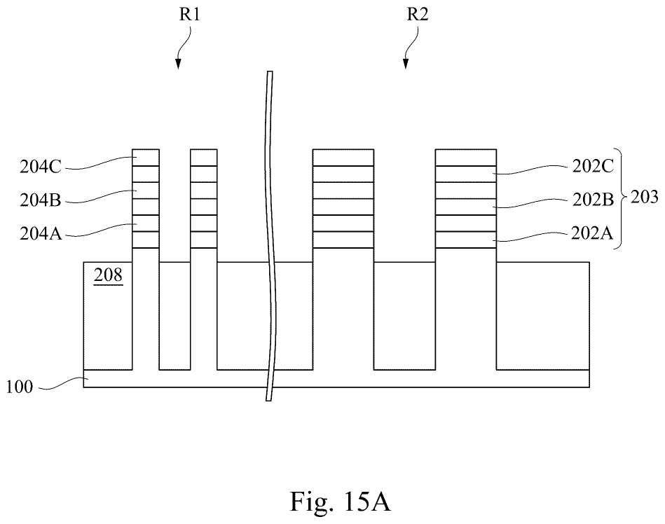

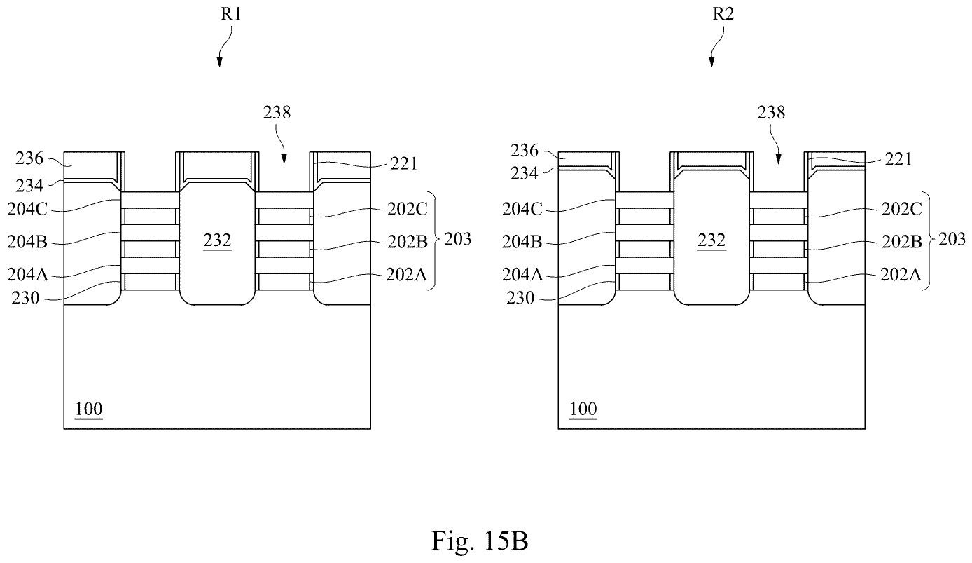

Reference is made to FIGS. 15A and 15B. FIGS. 15A and 15B illustrate removal of dummy gate structures, in accordance with some embodiments.

In FIGS. 15A and 15B, the dummy gates 216, and the masks 218 if present, are removed in one or more etching steps, so that gate trenches 238 are formed between corresponding gate spacers 221. In some embodiments, portions of the dummy gate dielectrics 211 in the gate trenches 238 are also be removed. In some embodiments, the dummy gates 216 and the dummy gate dielectrics 211 are removed by an anisotropic dry etch process. For example, the etching process may include a dry etch process using reaction gas(es) that selectively etch the dummy gates 216 at a faster rate than the protective layer 237 or the first spacers 221. Each gate trench 238 exposes and/or overlies portions of nanostructures 204, which will serve as channel regions in subsequently completed GAA-FETs. The nanostructures 204 serving as the channel regions are disposed between neighboring pairs of the epitaxial source/drain regions 232. During the removal, the dummy dielectric layers 211 may be used as etch stop layers when the dummy gates 216 are etched. The dummy dielectric layers 211 may then be removed after the removal of the dummy gates 216.

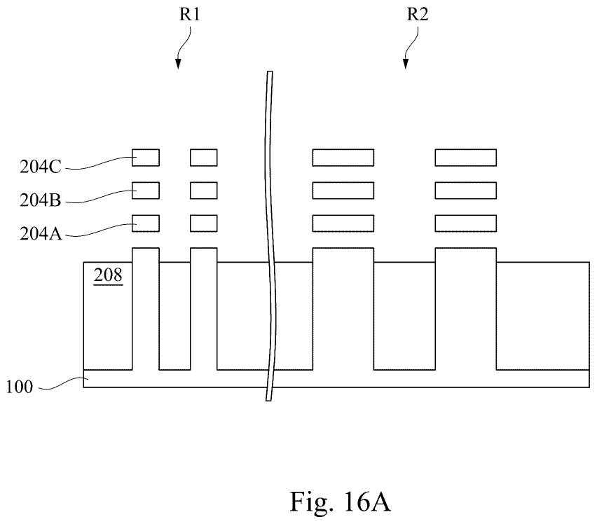

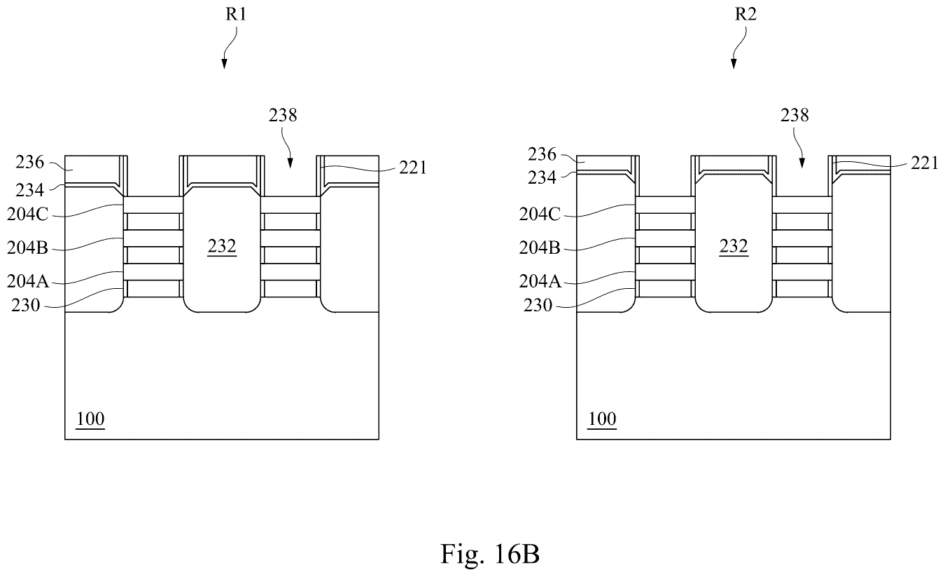

Reference is made to FIGS. 16A and 16B. FIGS. 16A and 16B illustrate removal of the nanostructures 202, in accordance with some embodiments.

In FIGS. 16A and 16B, the first nanostructures 202 in the gate trenches are removed by an isotropic etching process such as wet etching or the like using etchants which are selective to the materials of the first nanostructures 202. Stated differently, the first nanostructures 202 are removed by using a selective etching process that etches the first nanostructures 202 at a faster etch rate than it etches the second nanostructures 204, thus forming spaces between the second nanostructures 204 (also referred to as sheet-to-sheet spaces if the nanostructures 204 are nanosheets). This step can be referred to as a channel release process. At this interim processing step, the spaces between second nanostructures 204 may be filled with ambient environment conditions (e.g., air, nitrogen, etc). In some embodiments, the second nanostructures 204 can be referred to as nanosheets, nanowires, nanoslabs, nanorings having nano-scale size (e.g., a few nanometers), depending on their geometry. For example, in some embodiments the second nanostructures 204 may be trimmed to have a substantial rounded shape (i.e., cylindrical) due to the selective etching process for completely removing the first nanostructures 202. In that case, the resultant second nanostructures 204 can be called nanowires.

In embodiments in which the first nanostructures 202 include, e.g., SiGe, and the second nanostructures 204 include, e.g., Si or SiC, tetramethylammonium hydroxide (TMAH), ammonium hydroxide (NH₄OH) or the like may be used to remove the first nanostructures 202. In some embodiments, both the channel release step and the previous step of laterally recessing first nanostructures 202 (i.e., the step as illustrated in FIGS. 10A-10B) use a selective etching process that etches first nanostructures 202 (e.g., SiGe) at a faster etch rate than etching second nanostructures 204 (e.g., Si), and therefore these two steps may use the same etchant chemistry in some embodiments. In this case, the etching time/duration of channel release step is longer than the etching time/duration of the previous step of laterally recessing first nanostructures 202, so as to completely remove the sacrificial nanostructures 202.

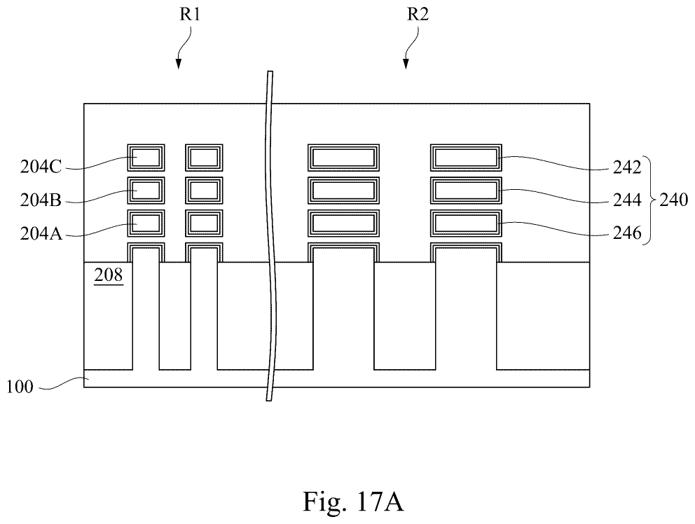

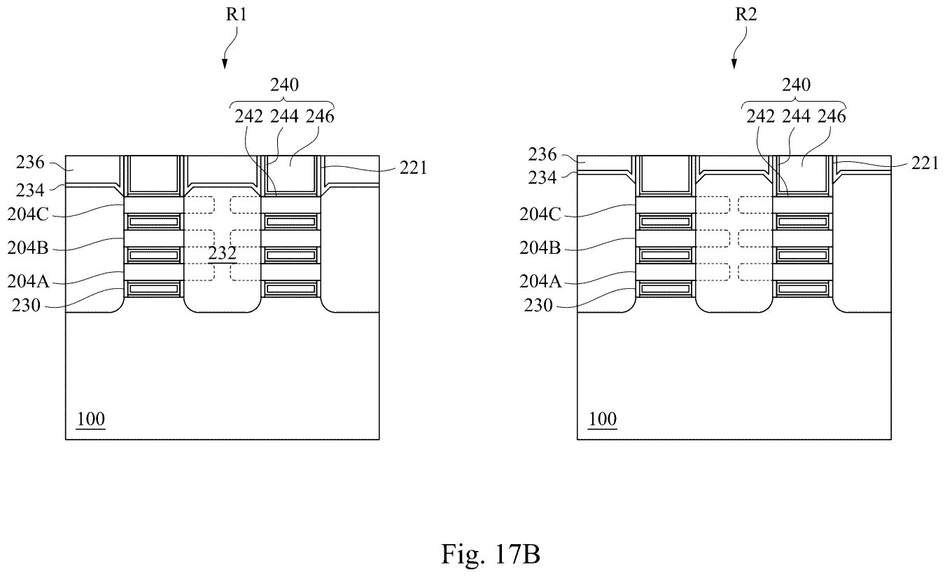

Reference is made to FIGS. 17A and 17B. FIGS. 17A and 17B illustrate formation of replacement gate structures 240, in accordance with some embodiments.

In FIGS. 17A and 17B, replacement gate structures 240 are respectively formed in the gate trenches 238 to surround each of the nanosheets 204 suspended in the gate trenches 238. The gate structures 240 may be final gates of GAA FETs. The final gate structure may be a high-k/metal gate stack, however other compositions are possible. In some embodiments, each of the gate structures 240 forms the gate associated with the multi-channels provided by the plurality of nanosheets 204. For example, high-k/metal gate structures 240 are formed within the sheet-to-sheet spaces provided by the release of nanosheets 204. In various embodiments, the high-k/metal gate structure 240 includes an interfacial layer 242 formed around the nanosheets 204, a high-k gate dielectric layer 244 formed around the interfacial layer 242, and a gate metal layer 246 formed around the high-k gate dielectric layer 244 and filling a remainder of gate trenches 238. Formation of the high-k/metal gate structures 240 may include one or more deposition processes to form various gate materials, followed by a CMP process to remove excessive gate materials, resulting in the high-k/metal gate structures 240 having top surfaces level with a top surface of the protective layer 237. As illustrated in the cross-sectional view of FIG. 18A, the high-k/metal gate structure 240 surrounds each of the nanosheets 204, and thus is referred to as a gate of a GAA FET.

In some embodiments, the interfacial layer 242 is silicon oxide formed on exposed surfaces of semiconductor materials in the gate trenches 238 by using, for example, thermal oxidation, chemical oxidation, wet oxidation or the like. As a result, surface portions of the nanosheets 204 exposed in the gate trenches 238 are oxidized into silicon oxide to form interfacial layer 242.

In some embodiments, the high-k gate dielectric layer 244 includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

In some embodiments, the gate metal layer 246 includes one or more metal layers. For example, the gate metal layer 246 may include one or more work function metal layers stacked one over another and a fill metal filling up a remainder of gate trenches 238. The one or more work function metal layers in the gate metal layer 246 provide a suitable work function for the high-k/metal gate structures 240. For an n-type GAA FET, the gate metal layer 246 may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type GAA FET, the gate metal layer 246 may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal in the gate metal layer 246 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

Reference is made to FIGS. 18A and 18B. FIGS. 18A and 18B illustrate formation of formation of source/drain contacts 250, in accordance with some embodiments. FIG. 18B illustrates schematic cross-sectional views of source/drain regions of the structure as illustrated in FIG. 18A, in accordance with some embodiments. FIG. 18B illustrates the source/drain regions 232, the nanostructures 204, the inner spacers 230, the STI regions 208 and the fin structures 206, and other elements are not illustrated in FIG. 18B for the purpose of simplicity and clarity.

In FIGS. 18A and 18B, source/drain contacts 250 are formed extending through the CESL 234 and the ILD layer 236. Formation of the source/drain contacts 250 includes, by way of example and not limitation, performing one or more etching processes to form contact openings extending though the ILD layer 236 and the CESL 234 to expose the source/drain epitaxy structures 232, depositing one or more metal materials (e.g., W, Ru, Co, Cu, Ti, TiN, Ta, TaN, Mo, Ni, the like or combinations thereof) overfilling the contact openings, and then performing a CMP process to remove excessive metal materials outside the contact openings.

In the cross-sectional view as illustrated in FIG. 18B, in some embodiments, the source/drain region 232 has an upper inclined surface inclined at an angle θ3 relative to the <001> direction. In some embodiments, the angle θ3 is about 35.3 degrees. In the cross-sectional view as illustrated in FIG. 18B, in some embodiments, the source/drain region 232 has a lower inclined surface inclined at an angle θ4 relative to a top surface of the STI regions 208. In some embodiments, the angle θ4 is about 35.3 degrees.

As illustrated in FIGS. 18A and 18B, a semiconductor structure 200 is formed. The semiconductor structure 200 includes the nanostructures 204 with the width W1 in the region R1 and the nanostructures 204 with the width W2 in the region R2. The width W1 is less than the width W2. The source/drain regions 232 in the region R1 have top surfaces lower than top surfaces of the source/drain regions 232 in the region R2. In some embodiments, a height difference between the source/drain regions 232 in the regions R1 and R2 is less than 5 nm. In some embodiments, the source/drain regions 232 include silicon germanium doped with boron. As illustrated in FIG. 18A, the dashed line present the boundaries of the semiconductor material layers 232B of the source/drain regions 232. In some embodiments, a difference between the gap G1 of the adjacent second semiconductor material layers 232B in the region R1 and the gap G2 of the adjacent second semiconductor material layers 232B in the region R2 is less than 5 nm. The height difference between the source/drain regions 232 in the regions R1 and R2 can be less than 50 nm. In some embodiments, the second semiconductor material layers 232B in the region R1 merge and can be a gap-free semiconductor material layer, and he second semiconductor material layers 232B in the region R2 merge and can be also a gap-free semiconductor material layer.

According to one or more embodiments of the present disclosure, a method of forming a semiconductor structure includes a number of operations. A plurality of channel regions is formed over a substrate. First semiconductor material layers are formed on opposite sides of the channel regions, wherein growth rates of the first semiconductor material layers along a <110> direction and a <100> direction are controlled so that from a top view, an angle from a sidewall of one of the first semiconductor material layers to an interface of the one of the first semiconductor material layers and one of the channel regions is in a range from about 54 degrees to about 90 degrees. Second semiconductor material layers are formed over the first semiconductor material layers, wherein the first and second semiconductor material layers form source/drain regions on the opposite sides of the channel regions. A gate structure is formed and wraps around the channel regions. In one or more embodiments of the present disclosure, the channel regions comprise a first channel region and a second channel region, and a width of the first channel region is less from the second channel region. In some embodiments, the source/drain regions comprises a first source/drain region on the first channel region and a second source/drain region on the second channel region, and a height difference between the first and second source/drain regions is less than 50 nm. In some embodiments, the first semiconductor material layers on the first channel region have a first gap, and the second semiconductor material layers on the second channel region have a second gap, a difference between the first and second gaps is less than 5 nm. In some embodiments, the first semiconductor material layers merge. In some embodiments, the width of the second channel region is in a range from about 5 nm to about 200 nm. In one or more embodiments of the present disclosure, one of the first semiconductor material layers has a rectangular profile from the top view.

According to one or more embodiments of the present disclosure, a method of forming a semiconductor structure includes a number of operations. A first channel region is formed over a substrate. A second channel region is formed over the substrate, wherein a width of the first channel region is less than a width of the second channel region. First semiconductor material layers are formed on opposite sides of the first and second channel regions. Second semiconductor material layers are formed on the first semiconductor material layers, wherein a process temperature of forming the second semiconductor material layers is less than a process temperature of forming the first semiconductor material layers. Third semiconductor material layers are formed over the second semiconductor material layers, wherein the first, second and third semiconductor material layers form first source/drain regions on the opposite sides of the first channel regions and second source/drain regions on the opposite sides of the second channel regions. A first gate structure is formed over the first channel region. A second gate structure is formed over the second channel region. In one or more embodiments of the present disclosure, the second semiconductor material layers merge. In one or more embodiments of the present disclosure, the first, second and third semiconductor material layers comprises silicon germanium doped with boron. In some embodiments, a boron concentration of the second semiconductor material layers is less than a boron concentration of the third semiconductor material layers. In some embodiments, a germanium atomic concentration of the second semiconductor material layers is less than a germanium atomic concentration of the third semiconductor material layers. In one or more embodiments of the present disclosure, the process temperature of the first semiconductor material layers are in a range from about 500° C. to about 650° C. In one or more embodiments of the present disclosure, the process temperature of the second semiconductor material layers are in a range from about 400° C. to about 550° C. In one or more embodiments of the present disclosure, the process temperature of the third semiconductor material layers are in a range from about 400° C. to about 450° C.

According to one or more embodiments of the present disclosure, a semiconductor structure includes a first channel region, a second channel region, first source/drain regions, second source/drain regions and a gate structure. The first channel region is over a substrate. The second channel region is over the substrate. A width of the first channel region is less than a width of the second channel region. The first source/drain regions are on opposite sides of the first channel region. The second source/drain regions are on opposite sides of the second channel region. One of the first and second source/drain regions includes a first semiconductor material layer, a second semiconductor material layer and a third semiconductor material layer. The second semiconductor material layer is over the first semiconductor material layer. From a top view, an angle from a sidewall of the second semiconductor material layer to an interface of the second semiconductor material layer and one of the first and second channel regions is in a range from about 54 degrees to about 90 degrees. The third semiconductor material layer is over the second semiconductor material layer. The gate structure wraps around the first and second channel regions. In one or more embodiments of the present disclosure, the width of the second channel region is in a range from about 5 nm to about 200 nm. In one or more embodiments of the present disclosure, the second semiconductor material layer has a rectangular profile from the top view. In one or more embodiments of the present disclosure, the second semiconductor material layer is a gap-free semiconductor material layer. In one or more embodiments of the present disclosure, the first, second and third semiconductor material layers comprises silicon germanium doped with boron.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a plurality of channel regions over a substrate;
forming first semiconductor material layers on opposite sides of the channel regions, wherein growth rates of the first semiconductor material layers along a <110> direction and a <100> direction are controlled so that from a top view, an angle from a sidewall of one of the first semiconductor material layers to an interface of the one of the first semiconductor material layers and one of the channel regions is in a range from about 54 degrees to about 90 degrees;
forming second semiconductor material layers over the first semiconductor material layers, wherein the first and second semiconductor material layers form source/drain regions on the opposite sides of the channel regions; and
forming a gate structure wrapping around the channel regions.

2. The method of claim 1, wherein the channel regions comprise a first channel region and a second channel region, and a width of the first channel region is less from the second channel region.

3. The method of claim 2, wherein the source/drain regions comprises a first source/drain region on the first channel region and a second source/drain region on the second channel region, and a height difference between the first and second source/drain regions is less than 50 nm.

4. The method of claim 2, wherein the first semiconductor material layers on the first channel region have a first gap, and the second semiconductor material layers on the second channel region have a second gap, a difference between the first and second gaps is less than 5 nm.

5. The method of claim 2, wherein the first semiconductor material layers merge.

6. The method of claim 2, wherein the width of the second channel region is in a range from about 5 nm to about 200 nm.

7. The method of claim 1, wherein one of the first semiconductor material layers has a rectangular profile from the top view.

8. A method, comprising:
forming a first channel region over a substrate;
forming a second channel region over the substrate, wherein a width of the first channel region is less than a width of the second channel region;
forming first semiconductor material layers on opposite sides of the first and second channel regions;
forming second semiconductor material layers on the first semiconductor material layers, wherein a process temperature of forming the second semiconductor material layers is less than a process temperature of forming the first semiconductor material layers;
forming a third semiconductor material layers over the second semiconductor material layers, wherein the first, second and third semiconductor material layers form first source/drain regions on the opposite sides of the first channel regions and second source/drain regions on the opposite sides of the second channel regions;
forming a first gate structure over the first channel region; and
forming a second gate structure over the second channel region.

9. The method of claim 8, wherein the second semiconductor material layers merge.

10. The method of claim 8, wherein the first, second and third semiconductor material layers comprises silicon germanium doped with boron.

11. The method of claim 10, wherein a boron concentration of the second semiconductor material layers is less than a boron concentration of the third semiconductor material layers.

12. The method of claim 10, wherein a germanium atomic concentration of the second semiconductor material layers is less than a germanium atomic concentration of the third semiconductor material layers.

13. The method of claim 8, wherein the process temperature of the first semiconductor material layers are in a range from about 500 ° C. to about 650 ° C.

14. The method of claim 8, wherein the process temperature of the second semiconductor material layers are in a range from about 400 ° C. to about 550 ° C.

15. The method of claim 8, wherein the process temperature of the third semiconductor material layers are in a range from about 400 ° C. to about 450 ° C.

16. A semiconductor structure, comprising:
a first channel region over a substrate;
a second channel region over the substrate, wherein a width of the first channel region is less than a width of the second channel region;
first source/drain regions on opposite sides of the first channel region;
second source/drain regions on opposite sides of the second channel region, wherein one of the first and second source/drain regions comprises:
a first semiconductor material layer;
a second semiconductor material layer over the a first semiconductor material layers, wherein from a top view, an angle from a sidewall of the second semiconductor material layer to an interface of the second semiconductor material layer and one of the first and second channel regions is in a range from about 54 degrees to about 90 degrees; and
a third semiconductor material layer over the second semiconductor material layer; and
a gate structure wrapping around the first and second channel regions.

17. The semiconductor structure of claim 16, wherein the width of the second channel region is in a range from about 5 nm to about 200 nm.

18. The semiconductor structure of claim 16, wherein the second semiconductor material layer has a rectangular profile from the top view.

19. The semiconductor structure of claim 16, wherein the second semiconductor material layer is a gap-free semiconductor material layer.

20. The semiconductor structure of claim 16, wherein the first, second and third semiconductor material layers comprises silicon germanium doped with boron.
